(19) United States
(12) Patent Application Publication
(10) Pub. No.: US 2018/0075978 A1
(43) Pub. Date: Mar. 15, 2018

(54) PHOTOELECTRIC CONVERSION DEVICE

(71) Applicants: SUMITOMO CHEMICAL COMPANY, LIMITED, Tokyo (JP); NATIONAL UNIVERSITY CORPORATION TOTTORI UNIVERSITY, Tottori-shi, Tottori (JP)

(72) Inventors: Yasunori UETANI, Tsukuba-shi (JP); Toshiyuki ITOH, Tottori-shi (JP)

(73) Assignees: SUMITOMO CHEMICAL COMPANY, LIMITED, Tokyo (JP); NATIONAL UNIVERSITY CORPORATION TOTTORI UNIVERSITY, Tottori-shi, Tottori (JP)

(21) Appl. No.: 15/559,233

(22) PCT Filed: Mar. 24, 2016
(86) PCT No.: PCT/JP2016/059484

§ 371 Date: Sep. 18, 2017

(30) Foreign Application Priority Data
Mar. 30, 2015 (JP) 2015-069735
Aug. 27, 2015 (JP) 2015-168234

(51) Int. Cl. H01G 9/20; H01L 51/00

(52) U.S. Cl. CPC H01G 9/2009; H01L 51/424; H01G 9/2059; H01L 51/0047

(57) ABSTRACT

Provided is a photoelectric conversion device having high durability against light irradiation including a cathode, an anode, an active layer that is provided between the cathode and the anode and contains a perovskite compound, and an electron transport layer that is provided between the cathode and the active layer and contains a fullerene derivative represented by Formula (1) below:

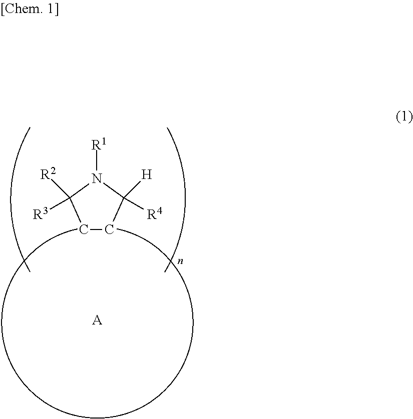

wherein, in Formula (1), Ring A represents a fullerene skeleton; R¹, R², R³, and R⁴ represent a hydrogen atom, a halogen atom, an alkyl group, an aryl group, an arylalkyl group, a monovalent heterocyclic group, or a group represented by Formula (2) below; and n represents an integer of 1 or more;

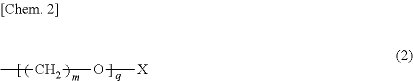

wherein, in Formula (2), m represents an integer of 1 to 6; q represents an integer of 1 to 4; X represents a hydrogen atom, an alkyl group, or an aryl group; when m is plurally present, a plurality of ms may be the same or different.

### TECHNICAL FIELD

The present invention relates to a photoelectric conversion device.

### BACKGROUND ART

In recent years, photoelectric conversion devices containing a perovskite compound as a material of an active layer have been proposed.

Reported is a photoelectric conversion device manufactured by forming a hole injection layer by applying a solution containing poly(3,4-ethylenedioxythiophene)/(poly(4-styrenesulfonic acid) (PEDOT/PSS) onto a patterned indium tin oxide (ITO) layer as a transparent electrode, further forming an active layer by applying a liquid containing a perovskite compound onto the hole injection layer, forming an electron transport layer by applying a liquid containing [6,6]-phenyl C61-butyric acid methyl ester (C60PCBM) as a fullerene derivative onto the active layer, and finally depositing a cathode onto the electron transport layer by vacuum evaporation (refer to Non Patent Document 1), for example.

### RELATED ART DOCUMENTS

Non Patent Document 1: Journal of Materials Chemistry A, 2014, Vol. 2, p. 15897

### DISCLOSURE OF INVENTION

### Problem to be Solved by the Invention

However, the photoelectric conversion device described in Non Patent Document 1 does not necessarily have sufficient durability against light irradiation.

An object of the present invention is to provide a photoelectric conversion device having high durability against light irradiation.

### Means for Solving Problem

The present invention provides [1] to [6] below.
[1] A photoelectric conversion device comprising:

a cathode;

an anode;

an active layer that is provided between the cathode and the anode and contains a perovskite compound; and

an electron transport layer that is provided between the cathode and the active layer and contains a fullerene derivative represented by Formula (1) below:

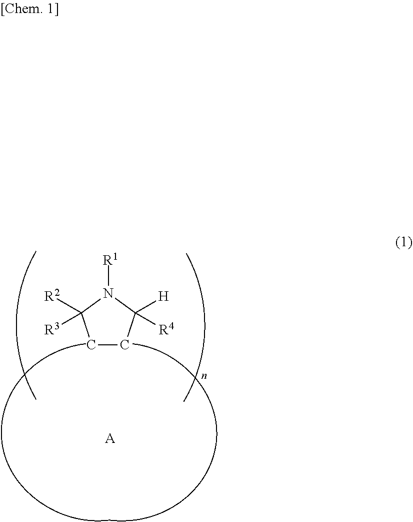

wherein, in Formula (1), Ring A represents a fullerene skeleton; R¹, R², R³, and R⁴ each independently represent a hydrogen atom, a halogen atom, an alkyl group optionally substituted with a halogen atom, an aryl group optionally having a substituent, an arylalkyl group optionally having a substituent, a monovalent heterocyclic group optionally having a substituent, or a group represented by Formula (2) below; and n represents an integer of 1 or more;

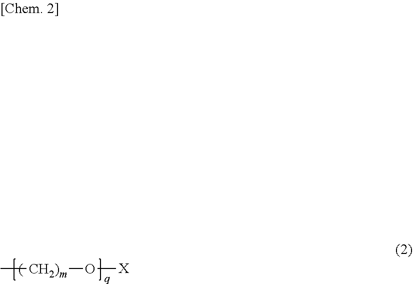

wherein, in Formula (2), m represents an integer of 1 to 6; q represents an integer of 1 to 4; X represents a hydrogen atom, an alkyl group, or an aryl group optionally having a substituent; when m is plurally present, a plurality of ms may be the same or different.
[2] The photoelectric conversion device according to above [1], wherein R¹ is a group represented by Formula (2).
[3] The photoelectric conversion device according to above [1] or [2], further comprising a supporting substrate, wherein

the supporting substrate, the anode, the active layer, the electron transport layer, and the cathode are provided in this order.
[4] The photoelectric conversion device according to any one of above [1] to [3], further comprising a hole injection layer that is provided between the anode and the active layer and contains one or more selected from the group consisting of an aromatic amine compound and a polymer compound containing a repeating unit having an aromatic amine residue.
[5] A solar cell module comprising the photoelectric conversion device according to any one of above [1] to [4].
[6] An organic optical sensor comprising the photoelectric conversion device according to any one of above [1] to [4].

The present invention can improve the durability of the photoelectric conversion device against light irradiation.

### DESCRIPTION OF EMBODIMENTS

The following describes the present invention in detail.

A photoelectric conversion device according to the present invention comprises a cathode, an anode, an active layer that is provided between the cathode and the anode and contains a perovskite compound, and an electron transport layer that is provided between the cathode and the active layer and contains a fullerene derivative represented by Formula (1).

(Perovskite Compound)

The perovskite compound is used as the material of the active layer of the photoelectric conversion device according to the present invention. In the present specification, the perovskite compound refers to a compound having the perovskite structure. The perovskite compound is preferably a perovskite compound having an organic substance and an inorganic substance as components of the perovskite structure (a perovskite compound having an organic-inorganic hybrid structure).

Further, the perovskite compound in the present invention is preferably a compound represented by Formula (3), Formula (4), or Formula (5) below and more preferably a compound represented by Formula (3) below.

CH₃NH₃M¹X¹₃ (3)

In Formula (3), M¹ is a divalent metal (such as Cu, Ni, Mn, Fe, Co, Pd, Ge, Sn, Pb, or Eu), and the three X¹ are each independently F, Cl, Br, or I.

Among the compounds represented by Formula (3), more preferred are CH₃NH₃PbI₃, CH₃NH₃PbCl₃, CH₃NH₃PbBr₃, CH₃NH₃SnI₃, CH₃NH₃SnCl₃, CH₃NH₃SnBr₃, and the like.

(R¹⁰NH₃)₂M¹X¹₄ (4)

In Formula (4), R¹⁰ is an alkyl group having 2 or more carbon atoms, an alkenyl group, an aralkyl group, an aryl group, a monovalent heterocyclic group, or a monovalent aromatic heterocyclic group, M¹ is a divalent metal (such as Cu, Ni, Mn, Fe, Co, Pd, Ge, Sn, Pb, or Eu), and the four X¹ are each independently F, Cl, Br, or I.

HC(═NH)NH₂M¹X¹₃ (5)

In Formula (5), M¹ is a divalent metal (such as Cu, Ni, Mn, Fe, Co, Pd, Ge, Sn, Pb, or Eu), and the three X¹ are each independently F, Cl, Br, or I.

In Formula (4), the alkyl group represented by R¹⁰ may be linear or branched or a cycloalkyl group. The number of carbon atoms in the alkyl group represented by R¹⁰ is generally 2 to 40 and preferably 2 to 30.

Examples of the alkyl group represented by R¹⁰ may include an ethyl group, a propyl group, an isopropyl group, a tert-butyl group, a pentyl group, a hexyl group, an octyl group, an isooctyl group, a nonyl group, a dodecyl group, a tridecyl group, a tetradecyl group, a pentadecyl group, an octadecyl group, an icosanyl group, a docosanyl group, a triacontanyl group, a tetracontanyl group, a cyclopentyl group, and a cyclohexyl group.

The number of carbon atoms in the alkenyl group represented by R¹⁰ is generally 2 to 30 and preferably 2 to 20. Examples of the alkenyl group represented by R¹⁰ may include a vinyl group, a 1-propenyl group, a 2-propenyl group, a 2-butenyl group, an oleyl group, and an allyl group.

The number of carbon atoms in the aralkyl group represented by R¹⁰ is generally 7 to 40 and preferably 7 to 30. Examples of the aralkyl group represented by R¹⁰ may include a benzyl group, a phenylethyl group, a phenylpropyl group, a naphthylmethyl group, and a naphthylethyl group.

The number of carbon atoms in the aryl group represented by R¹⁰ is generally 6 to 30 and preferably 6 to 20. Examples of the aryl group represented by R¹⁰ may include a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenylyl group.

In the present specification, the monovalent heterocyclic group means a group obtained by eliminating one hydrogen atom bonded to a heterocycle from a heterocyclic compound, whereas the monovalent aromatic heterocyclic group means a group obtained by eliminating one hydrogen atom bonded to an aromatic heterocycle from an aromatic heterocyclic compound. The number of carbon atoms in the monovalent heterocyclic group represented by R¹⁰ is generally 1 to 30 and preferably 1 to 20. The number of carbon atoms in the monovalent aromatic heterocyclic group represented by R¹⁰ is generally 2 to 30 and preferably 2 to 20. Examples of the monovalent heterocyclic group or the monovalent aromatic heterocyclic group represented by R¹⁰ may include a pyrrolidyl group, an imidazolidinyl group, a morpholyl group, an oxazolyl group, an oxazolidinyl group, a furyl group, a thienyl group, a pyridyl group, a pyridadinyl group, a pyrimidinyl group, a pyrazinyl group, a triazinyl group, an imidazolyl group, a pyrazolyl group, a thiazolyl group, a quinazolinyl group, a carbazolyl group, a carbolinyl group, a diazacarbazolyl group, and a phthalazinyl group.

One perovskite compound alone may be used as the material of the active layer, or two or more ones may be used.

(Fullerene Derivative)

A fullerene derivative represented by Formula (1) below is used as the material of the electron transport layer of the photoelectric conversion device according to the present invention.

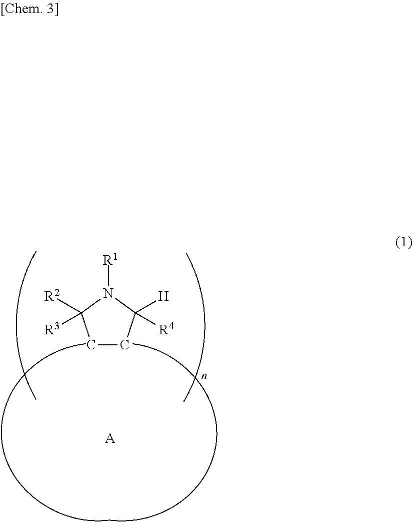

In Formula (1), Ring A represents a fullerene skeleton. R¹, R², R³, and R⁴ each independently represent a hydrogen atom, a halogen atom, an alkyl group optionally substituted with a halogen atom, an aryl group optionally having a substituent, an arylalkyl group optionally having a substituent, a monovalent heterocyclic group optionally having a substituent, or a group represented by Formula (2) below. n represents an integer of 1 or more.

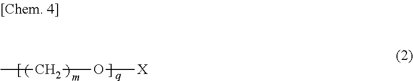

In Formula (2), m represents an integer of 1 to 6. q represents an integer of 1 to 4. X represents a hydrogen atom, an alkyl group, or an aryl group optionally having a substituent. When m is plurally present, ms may be the same or different from each other.

In Formula (1), n is preferably 1 or 2.

In Formula (2), m is preferably 2. In Formula (2), q is preferably 2.

In Formula (2), the number of carbon atoms in the alkyl group represented by X is generally 1 to 30 and preferably 1 to 20. The number of the carbon atoms in aryl group in the “aryl group optionally having a substituent” represented by X is generally 6 to 30 and preferably 6 to 20. X is preferably a hydrogen atom or an alkyl group, more preferably a hydrogen atom or an alkyl group having 1 to 5 carbon atoms, and further preferably a hydrogen atom or a methyl group.

In the fullerene derivative represented by Formula (1), R¹ is preferably a group represented by Formula (2).

In the present specification, “optionally having (has) a substituent” includes both an aspect in which all the hydrogen atoms contained in the compound or group are not replaced and an aspect in which part or the whole of one or more hydrogen atoms are replaced with substituents.

Examples of the substituent may include an alkyl group, an alkyl halide group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a halogen atom, an acyl group, an acyloxy group, an imine residue, a dialkylamino group, a diarylamino group, an amido group, an acid imide group, a monovalent heterocyclic group, a carboxy group, a substituted carboxy group, a cyano group, and a polymerizable substituent.

The “polymerizable substituent” represents a substituent that gives rise to a polymerization reaction to form bonds between or among two or more molecules and can produce a compound. Examples of such a group may include groups having a carbon-carbon multiple bond (examples thereof may include a vinyl group, an ethynyl group, a butenyl group, an acryloyl group, a group obtained by eliminating one hydrogen atom from an acrylate, a group obtained by eliminating one hydrogen atom from acryl amide, a mathacryloyl group, a group obtained by eliminating one hydrogen atom from a methacrylate, a group obtained by eliminating one hydrogen atom from methacryl amide, a group obtained by eliminating one hydrogen atom from allene, an allyl group, a vinyloxy group, a vinylamino group, a furyl group, a pyrrolyl group, a thienyl group, a group obtained by eliminating one hydrogen atom from silole, and a group having a benzocyclobutene structure), groups having a small ring (for examples, a cyclopropyl group, a cyclobutyl group, an epoxy group, a group having an oxetane structure, a group having a diketene structure, or a group having an episulfide structure), a group having a lactone structure, a group having a lactam structure, and a group containing a siloxane derivative. Apart from the above groups, a combination of groups that can form an ester bond or an amido bond can also be used. Examples of such a combination of groups may include a combination of a hydrocarbyloxy carbonyl group and an amino group and a combination of a hydrocarbyloxy carbonyl group and a hydroxy group.

Examples of the fullerene skeleton represented by Ring A may include a fullerene skeleton originating from C₆₀ fullerene and a fullerene skeleton originating from a fullerene having 70 or more carbon atoms.

The fullerene skeleton represented by Ring A may be a fullerene skeleton with a certain group added. When the fullerene skeleton represented by Ring A has a plurality of groups, the groups may be bonded to each other. Examples of the group that the fullerene skeleton represented by Ring A may have may include an indane-1,3-diyl group and a methylene group optionally having a substituent.

Preferred examples of the substituent in the “methylene group optionally having a substituent” that the fullerene skeleton represented by Ring A can have may include an aryl group, a heteroaryl group, and hydrocarbyloxy carbonyl alkyl group.

The “methylene group optionally having a substituent” that the fullerene skeleton represented by Ring A can have is preferably a methylene group having an aryl group and a hydrocarbyloxy carbonyl alkyl group, more preferably a methylene group having a phenyl group and an alkoxycarbonyl propyl group, and further preferably a methylene group having a phenyl group and a methoxycarbonyl propyl group.

Consequently, the fullerene skeleton represented by Ring A may be a fullerene skeleton originating from phenyl C61-butyric acid methyl ester (C60PCBM) or a fullerene skeleton originating from phenyl C71-butyric acid methyl ester (C70PCBM).

Examples of the halogen atom represented by R¹, R², R³, and R⁴ may include a fluorine atom, a chlorine atom, a bromine atom, and an iodine atom.

The alkyl group in the “alkyl group optionally substituted with a halogen atom” represented by R¹, R², R³, and R⁴ may be linear or branched or a cycloalkyl group. The number of carbon atoms in the “alkyl group optionally substituted with a halogen atom” represented by R¹, R², R³, and R⁴ is generally 1 to 30 and preferably 1 to 20.

Examples of the halogen atom in the “alkyl group optionally substituted with a halogen atom” represented by R¹, R², R³, and R⁴ is similar to the examples of the halogen atom represented by R¹, R², R³, and R⁴.

The aryl group in the “aryl group optionally having a substituent” represented by R¹, R², R³, and R⁴ means a group obtained by eliminating one hydrogen atom bonded to an aromatic ring from an aromatic hydrocarbon. The number of carbon atoms in the aryl group is generally 6 to 60, preferably 6 to 16, and more preferably 6 to 10.

Specific examples of the aryl group may include a phenyl group, a 1-naphthyl group, and a 2-naphthyl group. Any of the hydrogen atoms within the aryl group is optionally substituted with a substituent; examples of the substituent may include an alkyl group, a halogen atom, an alkyl halide group, an alkoxy group, a dialkylamino group, a diarylamino group, a silyl group, and a substituted silyl group. Examples of the aryl group having the substituent may include a 3-methylphenyl group, a trimethylsilylphenyl group, a 2-methoxyphenyl group, a 4-methoxyphenyl group, a 2,4,5-trimethoxyphenyl group, a 4-(diphenylamino)-phenyl group, a 2-(dimethylamino)-phenyl group, a 3-fluorophenyl group, and a 4-(trifluoromethyl)-phenyl group.

The number of carbon atoms in the arylalkyl group in the “arylalkyl group optionally having a substituent” represented by R¹, R², R³, and R⁴ is generally 7 to 61, preferably 7 to 17, and more preferably 7 to 11. Specific examples of the arylalkyl group may include a benzyl group, a phenylethyl group, a phenylpropyl group, a naphthylmethyl group, and a naphthylethyl group.

The number of carbon atoms in the monovalent heterocyclic group in the “monovalent heterocyclic group optionally having a substituent” represented by R¹, R², R³, and R⁴ is generally 1 to 30 and preferably 1 to 20. Examples of the monovalent heterocyclic group in the “monovalent heterocyclic group optionally having a substituent” represented by R¹, R², R³, and R⁴ may include a thienyl group and a 2,2′-bithiophen-5-yl group.

When R⁴ is plurally present, R⁴s may be bonded to each other. When R⁴ is plurally present, that is, n representing an integer of 2 or more, examples of a substituent in which the R⁴s are bonded to each other may include a divalent group represented by Formula (3) below.

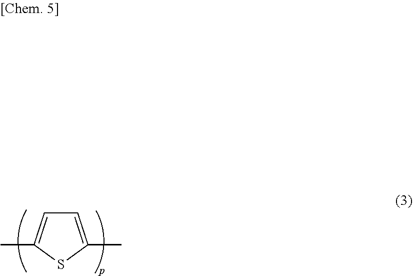

In Formula (3), p represents an integer of 1 to 5.

p is preferably an integer of 2 to 4 and is more preferably 3. The divalent group represented by Formula (3) optionally has a substituent.

Specific examples of the structure of the fullerene derivative represented by Formula (3) may include the structures below. The cyclic structures attached with the figures “60” and “70” in the structures below represent a C₆₀ fullerene skeleton and a C₇₀ fullerene skeleton, respectively.

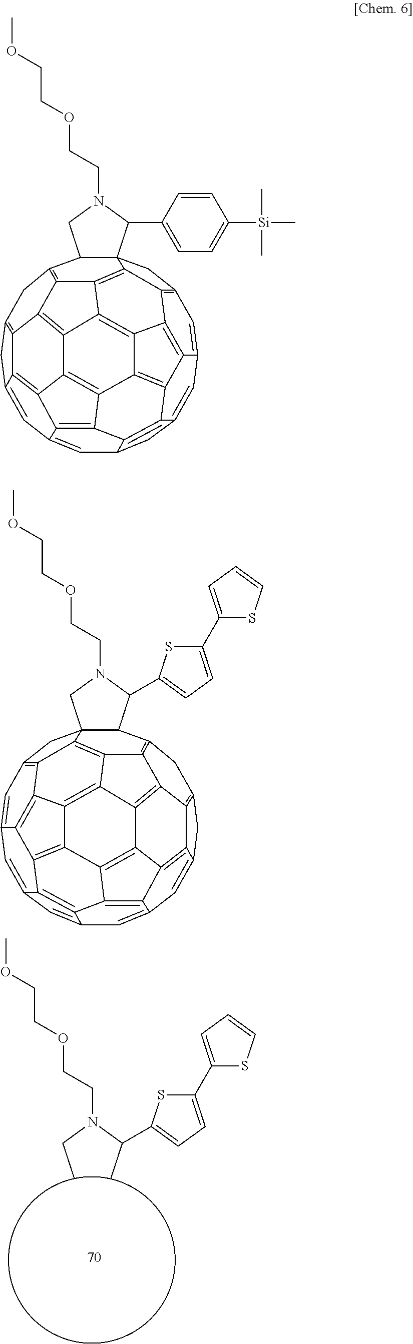 [SMILES: COCCOCCN1CC2C3=c4c5c6c7c(cc8cc9cc%10cc%11cc%12c%13c(c4c4c5c5c7c8c7c9c%10c8c%11c%13c4c8c75)=C(C3)C%12)CC62C1c1ccc([Si](C)(C)C)cc1 ; COCCOCCN1CC23Cc4cc5cc6cc7cc8cc9c%10c%11c%12c(c%13c2c4c2c5c4c6c7c5c8c%10c6c%12c%13c2c4c56)=C(CC=%11C9)C3C1c1ccc(-c2cccs2)s1 ; CCN(CCOCCOC)C(C)c1ccc(-c2cccs2)s1]

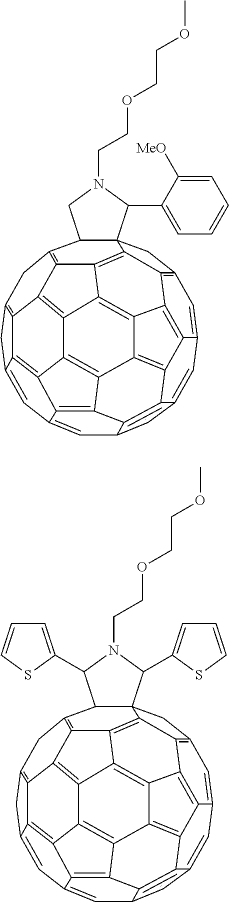 [SMILES: COCCOCCN1CC2C3=c4c5c6c7c(cc8cc9cc%10cc%11cc%12c%13c(c4c4c5c5c7c8c7c9c%10c8c%11c%13c4c8c75)=C(C3)C%12)CC62C1c1ccccc1OC ; COCCOCCN1C(c2cccs2)C2C3=c4c5c6c7c(cc8cc9cc%10cc%11cc%12c%13c(c4c4c5c5c7c8c7c9c%10c8c%11c%13c4c8c75)=C(C3)C%12)CC62C1c1cccs1]

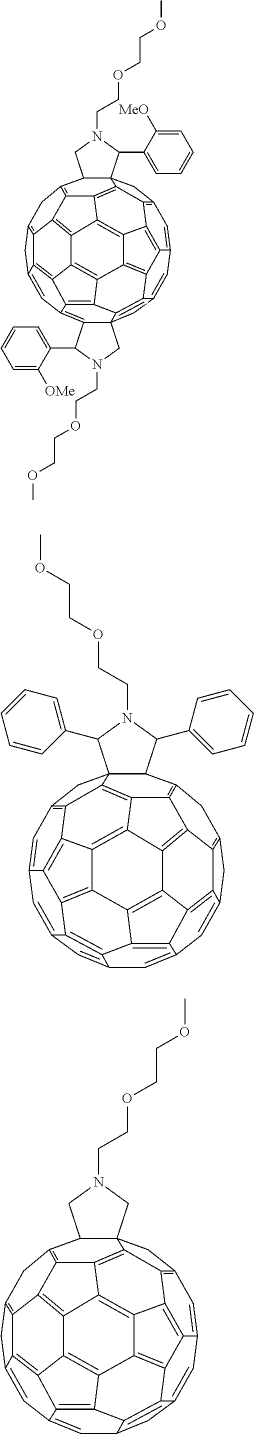

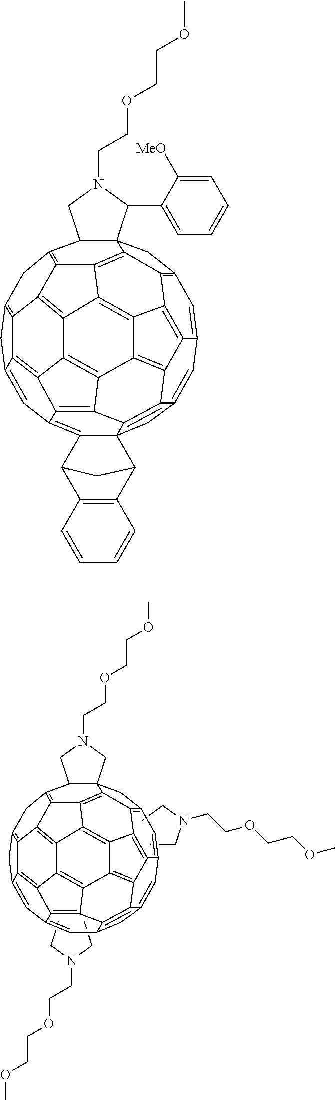

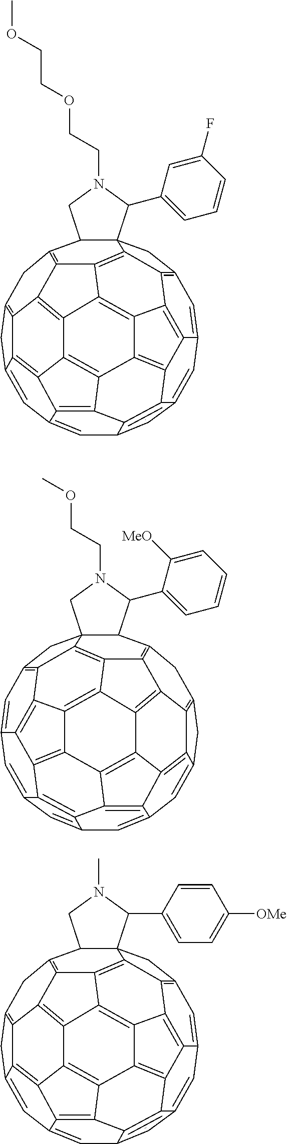

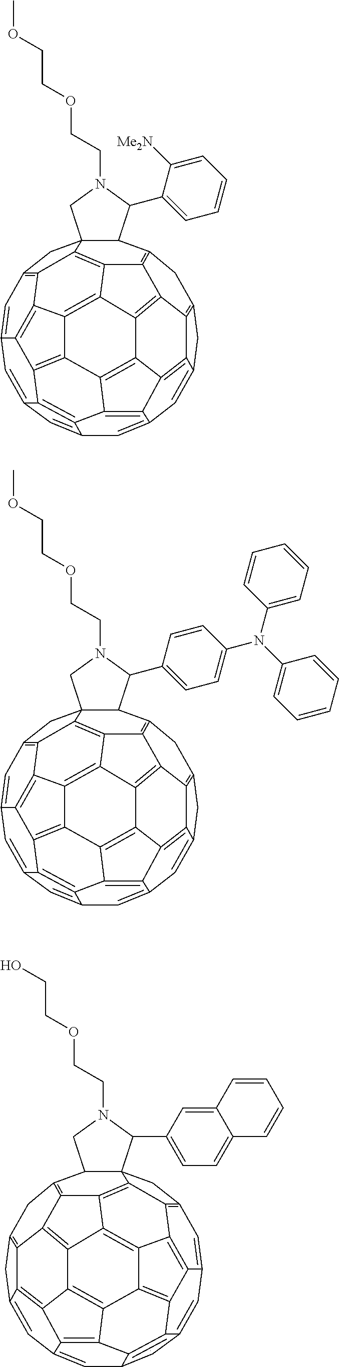 [SMILES: COCCOCCN1CC23Cc4cc5cc6cc7cc8cc9c%10c%11c%12c(c%13c2c4c2c5c4c6c7c5c8c%10c6c%12c%13c2c4c56)=C(CC=%11C9)C3C1c1ccccc1N(C)C ; COCCOCCN1CC23Cc4cc5cc6cc7cc8cc9c%10c%11c%12c(c%13c2c4c2c5c4c6c7c5c8c%10c6c%12c%13c2c4c56)=C(CC=%11C9)C3C1c1ccc(N(c2ccccc2)c2ccccc2)cc1 ; OCCOCCN1CC2C3=c4c5c6c7c(cc8cc9cc%10cc%11cc%12c%13c(c4c4c5c5c7c8c7c9c%10c8c%11c%13c4c8c75)=C(C3)C%12)CC62C1c1ccc2ccccc2c1]

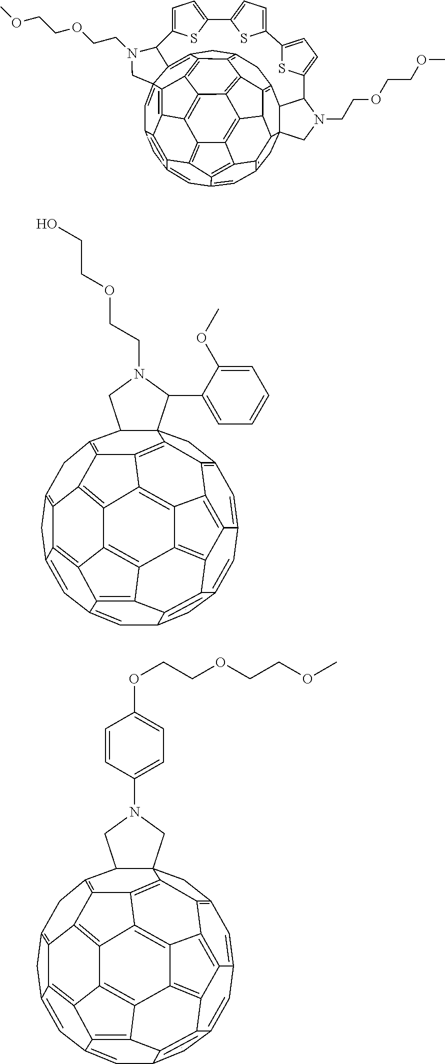

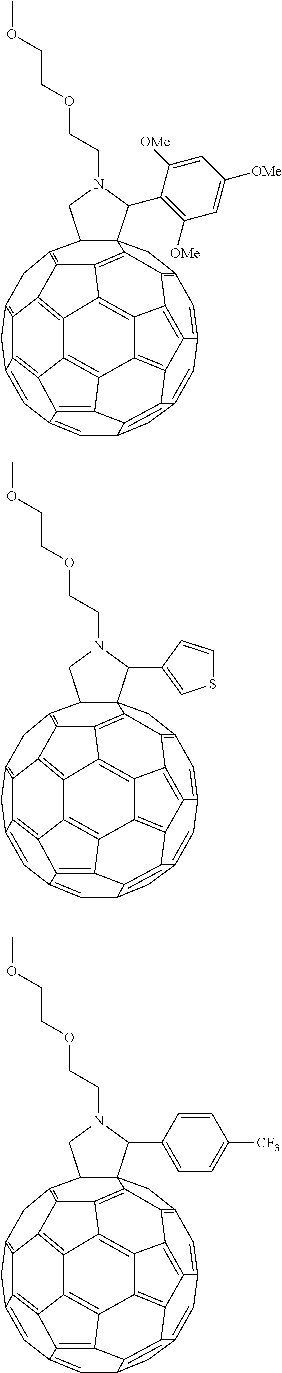 [SMILES: COCCOCCN1CC2C3=c4c5c6c7c(cc8cc9cc%10cc%11cc%12c%13c(c4c4c5c5c7c8c7c9c%10c8c%11c%13c4c8c75)=C(C3)C%12)CC62C1c1c(OC)cc(OC)cc1OC ; COCCOCCN1CC2C3=c4c5c6c7c(cc8cc9cc%10cc%11cc%12c%13c(c4c4c5c5c7c8c7c9c%10c8c%11c%13c4c8c75)=C(C3)C%12)CC62C1c1ccsc1 ; COCCOCCN1CC2C3=c4c5c6c7c(cc8cc9cc%10cc%11cc%12c%13c(c4c4c5c5c7c8c7c9c%10c8c%11c%13c4c8c75)=C(C3)C%12)CC62C1c1ccc(C(F)(F)F)cc1]

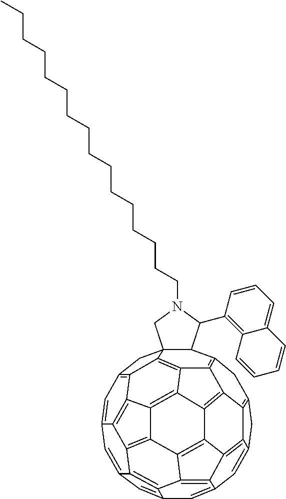 [SMILES: CCCCCCCCCCCCCCCCN1CC23Cc4cc5cc6cc7cc8cc9c%10c%11c%12c(c%13c2c4c2c5c4c6c7c5c8c%10c6c%12c%13c2c4c56)=C(CC=%11C9)C3C1c1cccc2ccccc12]

For the electron transport layer of the photoelectric conversion device according to the present invention, one fullerene derivative represented by Formula (1) alone may be used, or two or more fullerene derivatives may be used.

The fullerene derivative represented by Formula (1) described as above can be produced by any conventionally known method. The fullerene derivative represented by Formula (1) can be produced by a method using a 1,3-dipole cycloaddition reaction of an iminium cation produced through decarboxylation from an imine produced from a glycine derivative and an aldehyde and a fullerene, for example. Such a method is disclosed in Japanese Patent Application Laid-open No. 2009-67708, Japanese Patent Application Laid-open No. 2009-84264, Japanese Patent Application Laid-open No. 2011-241205, and Japanese Patent Application Laid-open No. 2011-77486, for example.

In producing the fullerene derivative represented by Formula (1), reaction conditions such as reaction time and reaction temperature and the amount of use of reaction raw materials (the glycine derivative, the aldehyde, and the fullerene, for example) are adjusted as appropriate, whereby the number of “n” in the fullerene derivative represented by Formula (1) can be adjusted.

(Photoelectric Conversion Device)

The following describes the cathode, the anode, the active layer, the electron transport layer, and other components (such as a hole injection layer) included as needed included in the photoelectric conversion device according to the present invention in detail.

(Embodiment of Photoelectric Conversion Device)

As already described, the photoelectric conversion device according to the present invention includes a pair of electrodes (the anode and the cathode) and the active layer provided between the pair of electrodes. The electron transport layer is provided between the cathode and the active layer.

(Supporting Substrate)

The photoelectric conversion device according to the present invention is generally produced on a supporting substrate. For the supporting substrate, a substrate is suitably used that is formed of a material that does not chemically change when the photoelectric conversion device is produced by forming the electrodes and forming layers of organic substances. Examples of the material of the supporting substrate may include glass, plastic, polymer film, and silicon. For the photoelectric conversion device of a type that takes in light from the supporting substrate side, a substrate having high light transmittance is suitably used for the supporting substrate. When the photoelectric conversion device is produced on an opaque supporting substrate, light cannot be taken in through the supporting substrate. For this reason, an electrode on a far side from the supporting substrate is preferably transparent or semi-transparent. Owing to the electrode on the far side from the supporting substrate being transparent or semi-transparent, light can be taken in through the electrode on the far side from the supporting substrate when the opaque supporting substrate is used.

(Electrodes)

The electrodes are formed of a conductive material. For the material of the electrode, metals, metal oxides, and organic substances such as conductive polymers can be used, for example. Examples of the material of the electrodes may include metals such as lithium, sodium, potassium, rubidium, cesium, magnesium, calcium, strontium, barium, aluminum, scandium, vanadium, zinc, yttrium, indium, cerium, samarium, europium, terbium, ytterbium, gold, silver, platinum, copper, manganese, titanium, cobalt, nickel, tungsten, and tin, alloys containing two or more metals selected from the group consisting of these metals, indium oxide, zinc oxide, tin oxide, ITO, fluorinated tin oxide (FTO), indium zinc oxide (IZO), graphite, and graphite intercalation compounds. Examples of the alloys may include a magnesium-silver alloy, a magnesium-indium alloy, a magnesium-aluminum alloy, an indium-silver alloy, a lithium-aluminum alloy, a lithium-magnesium alloy, a lithium-indium alloy, and a calcium-aluminum alloy. Examples of the conductive polymers may include polyaniline and derivatives thereof and polythiophene and derivatives thereof.

The electrodes may be a single layer or a plurality of layers stacked.

At least either of the anode and the cathode is preferably transparent or semi-transparent. The perovskite compound contained in the active layer of the photoelectric conversion device according to the present invention generally has a crystalline structure, and light made incident on the transparent or semi-transparent electrode is absorbed by the perovskite compound having the crystalline structure to generate electrons and holes within the active layer. The generated electrons and holes move within the active layer to reach different electrodes and are thereby taken out as electric energy (a current) to the outside of the photoelectric conversion device.

Examples of the material of the transparent or semi-transparent electrode may include conductive metal oxides and metals; when these materials are not transparent, they are formed to be a thin film that is thin enough to pass light, whereby they can be formed to be the transparent or semi-transparent electrode. Specific examples of the material of the transparent or semi-transparent electrode may include indium oxide, zinc oxide, tin oxide, ITO, IZO, FTO, NESA as complexes thereof, gold, platinum, silver, copper, and aluminum. The material of the transparent or semi-transparent electrode preferably contains one or more selected from ITO, IZO, and tin oxide and is more preferably one or more selected from ITO, IZO, and tin oxide.

The surface of the electrodes may be subjected to treatment such as ozone UV treatment, corona treatment, or ultrasonic treatment.

(Method for Forming Electrodes)

A method for forming the electrodes is not limited to a particular method; the material of the electrodes can be formed on a layer on which the electrodes are to be formed or on the supporting substrate by vacuum evaporation, sputtering, ion plating, plating, or coating method, for example. When the material of the electrodes is polyaniline or derivatives thereof, polythiophene or derivatives thereof, or an emulsion or suspension containing nanoparticles, nanowires, or nanotubes or the like, the electrodes can be preferably formed by coating method. When the material of the electrodes contains a conductive substance, the electrodes may be formed by coating method using a coating liquid, a metallic ink, a metallic paste, a molten low melting point metal, or the like containing the conductive substance. Examples of a method for applying the coating liquid or the like may include spin coating method, casting method, micro gravure coating method, gravure coating method, bar coating method, roll coating method, wire bar coating method, dip coating method, spray coating method, screen printing method, flexo printing method, offset printing method, inkjet printing method, dispenser printing method, nozzle coating method, and capillary coating method; among these methods, preferred are spin coating method, flexo printing method, inkjet printing method, and dispenser printing method.

Examples of the conductive substance that can be contained in the emulsion or the suspension may include metals such as gold and silver, oxides such as ITO, and carbon nanotubes. The electrodes may be formed of nanoparticles or nanofibers alone. In the electrodes, nanoparticles or nanofibers may be dispersed in a certain medium such as a conductive polymer as disclosed in Translation of PCT Application No. 2010-525526.

Examples of a solvent for the coating liquid used when the electrodes are formed by coating method may include hydrocarbon solvents such as toluene, xylene, mesitylene, tetralin, decalin, bicyclohexyl, n-butylbenzene, sec-butylbenzene, and tert-butylbenzene; halogenated saturated hydrocarbon solvents such as carbon tetrachloride, chloroform, dichloromethane, dichloroethane, chlorobutane, bromobutane, chloropentane, bromopentane, chlorohexane, bromohexane, chlorocyclohexane, and bromocyclohexane; halogenated unsaturated hydrocarbon solvents such as chlorobenzene, dichlorobenzene, and trichlorobenzene; ether solvents such as tetrahydrofuran and tetrahydropyran; water; and alcohols. Specific examples of the alcohols may include methanol, ethanol, isopropanol (2-propanol), butanol, ethylene glycol, propylene glycol, butoxyethanol, and methoxybutanol. The coating liquid used in the present invention may contain two or more solvents or contain two or more of the solvents exemplified above.

(Active Layer)

The active layer is a layer having a function of converting optical energy into electric energy.

The active layer of the photoelectric conversion device according to the present invention contains the perovskite compound. Specific examples and preferred examples of the perovskite compound are as described above.

The active layer may contain other components apart from the perovskite compound. Examples of the other components that the active layer can contain may include electron donor compounds, electron acceptor compounds, ultraviolet absorbers, antioxidants, sensitizers for sensitizing a function of generating electric charges through absorbed light, photostabilizers for enhancing stability against ultraviolet rays, and binders for enhancing mechanical characteristics.

(Method for Forming Active Layer)

A method for forming the active layer containing the perovskite compound is not limited to a particular method. Examples of the method for forming the active layer may include coating method. In view of further simplifying the formation process of the active layer, the active layer containing the perovskite compound is preferably formed by coating method. A coating liquid for use in coating method may be a solution containing the perovskite compound or a solution containing a precursor that can be converted into a perovskite compound through a self-organizing reaction after the formation of the layer. Examples of such a precursor may include CH₃NH₃PbI₃, CH₃NH₃PbBr₃, (CH₃(CH₂)ₙCHCH₃NH₃)₂PbI₄ (where n is an integer of 5 to 8), and (C₆H₅C₂H₄NH₃)₂PbBr₄.

The active layer containing the perovskite compounded represented by Formula (3) to Formula (5) can also be formed by a method that applies a solution containing a metal halide onto a layer on which the active layer is to be formed and then further applying a solution containing an ammonium halide and a solution containing an amine halide or a formamidine hydrohalide onto the formed metal halide film or a method that immerses the formed metal halide film in a solution containing an ammonium halide and a solution containing an amine halide or a formamidine hydrohalide.

The active layer containing the perovskite compound can be formed by applying, for example, a solution containing lead iodide and applying a solution containing methylammonium iodide onto the formed lead iodide film onto the layer on which the active layer is to be formed.

Examples of a method for applying the coating liquid containing the perovskite compound, the solution containing the metal halide, the solution containing the ammonium halide, and the solution containing the amine halide may include spin coating method, casting method, micro gravure coating method, gravure coating method, bar coating method, roll coating method, wire bar coating method, dip coating method, spray coating method, screen printing method, flexo printing method, offset printing method, inkjet printing method, dispenser printing method, nozzle coating method, and capillary coating method; among these methods, preferred are spin coating method, flexo printing method, inkjet printing method, and dispenser printing method.

When the active layer containing the perovskite compound is formed by coating method, the coating liquid used for coating method may contain a solvent apart from the perovskite compound or the precursor of the perovskite compound and preferably contains the solvent.

Examples of the solvent for preparing the coating liquid for forming the active layer may include esters (such as methyl formate, ethyl formate, propyl formate, pentyl formate, methyl acetate, ethyl acetate, and pentyl acetate); ketones (such as γ-butyrolactone, N-methyl-2-pyrrolidone, acetone, dimethyl ketone, diisobutyl ketone, cyclopentanone, cyclohexanone, and methylcyclohexanone); ethers (such as diethyl ether, methyl-tert-butyl ether, diisopropyl ether, dimethoxy methane, dimethoxy ethane, 1,4-dioxane, 1,3-dioxolane, 4-methyl dioxolane, tetrahydrofuran, methyl tetrahydrofuran, anisole, and phenetole); alcohols (such as methanol, ethanol, 1-propanol, 2-propanol, 1-butanol, 2-butanol, tert-butanol, 1-pentanol, 2-methyl-2-butanol, methoxypropanol, diacetone alcohol, cyclohexanol, 2-fluoroethanol, 2,2,2-trifluoroethanol, and 2,2,3,3-tetrafluoro-1-propanol); glycol ethers (cellosolves) (such as ethylene glycol monomethyl ether, ethylene glycol monoethyl ether, ethylene glycol monobutyl ether, ethylene glycol monoethyl ether acetate, and triethylene glycol dimethyl ether); amide solvents (such as N,N-dimethylformamide, acetamide, and N,N-dimethylacetamide); nitrile solvents (such as acetonitrile, isobutyronitrile, propionitrile, and methoxyacetonitrile); carbonate solvents (such as ethylene carbonate and propylene carbonate); halogenated hydrocarbons (such as methylene chloride, dichloromethane, and chloroform); hydrocarbons (such as n-pentane, cyclohexane, n-hexane, benzene, toluene, and xylene); and dimethylsulfoxide. The compounds contained in these solvents may have a branched structure or a cyclic structure and may have two or more of the functional groups of esters, ketones, ethers, and alcohols (that is, a group represented by —O—, a group represented by —(C═O)—, a group represented by —COO—, and a group represented by —OH). The hydrogen atoms in the hydrocarbon moiety of esters, ketones, ethers, and alcohols may be replaced with a halogen atom (in particular, a fluorine atom).

The coating liquid for forming the active layer may contain two or more solvents or may contain two or more of the solvents exemplified above.

There is no particular limit to the amount of the solvent used for the coating liquid. The amount of the solvent used is preferably 1 time or more and 10,000 times or less and more preferably 10 times or more and 1,000 times or less the perovskite compound or the precursor of the perovskite compound in terms of weight. The solvent is preferably 1 time or more and 10,000 times or less and more preferably 10 times or more and 1,000 times or less each of the metal halide, the ammonium halide, and the amine halide in terms of weight, for example.

The above describes the example in which the solution is used as the coating liquid for forming the active layer. However, the coating liquid is not limited to the example in the present invention and may be any solution, is not necessarily a solution, or a dispersion liquid such as an emulsion or a suspension.

After the coating of the coating liquid, the solvent is preferably removed in forming the active layer. Examples of a method for removing the solvent may include heating treatment, air-drying treatment, and vacuum treatment.

(Electron Transport Layer)

In the photoelectric conversion device according to the present invention, the electron transport layer is provided between the cathode and the active layer. The electron transport layer contains the fullerene derivative represented by Formula (1). Specific examples and preferred examples of the fullerene derivative represented by Formula (1) are as already described.

The electron transport layer may contain an electron transport material other than the fullerene derivative represented by Formula (1). The electron transport material that may be contained in the electron transport layer other than the fullerene derivative represented by Formula (1) may be an organic compound or an inorganic compound. Examples of the electron transport material as the organic compound may include electron transport materials as low molecular weight compounds and electron transport materials as polymer compounds exemplified below and carbon nanotubes. Examples of the electron transport material as the low molecular weight compounds may include oxadiazole derivatives, anthraquinodimethane and derivatives thereof, benzoquinone and derivatives thereof, naphthoquinone and derivatives thereof, anthraquinone and derivatives thereof, tetracyanoanthraquinodimethane and derivatives thereof, fluorenone derivatives, diphenyldicyanoethylene and derivatives thereof, diphenoquinone derivatives, metal complexes of 8-hydroxyquinoline and derivatives thereof, polyquinoline and derivatives thereof, polyquinoxaline and derivatives thereof, polyfluorene and derivatives thereof, fullerenes such as a C₆₀ fullerene and derivatives thereof, and phenanthrene derivatives such as bathocuproine. Examples of the electron transport material as the polymer compounds may include polyvinyl carbazole and derivatives thereof, polysilane and derivatives thereof, polysiloxane derivatives containing an aromatic amine structure on their side chains or main chains, polyaniline and derivatives thereof, polythiophene and derivatives thereof, polypyrrole and derivatives thereof, polyphenylenevinylene and derivatives thereof, polythienylenevinylene and derivatives thereof, and polyfluorene and derivatives thereof. Among these materials, the electron transporting material that may be contained in the electron transport layer other than the fullerene derivative represented by Formula (1) is preferably fullerenes and derivatives thereof (except the fullerene derivative represented by Formula (1)).

Examples of fullerenes and derivatives thereof may include a C₆₀ fullerene, a C₇₀ fullerene, fullerenes having a larger carbon atom number than that of the 0₇₀ fullerene, and derivatives thereof. Examples of the derivatives of the C₆₀ fullerene may include the fullerene derivatives below.

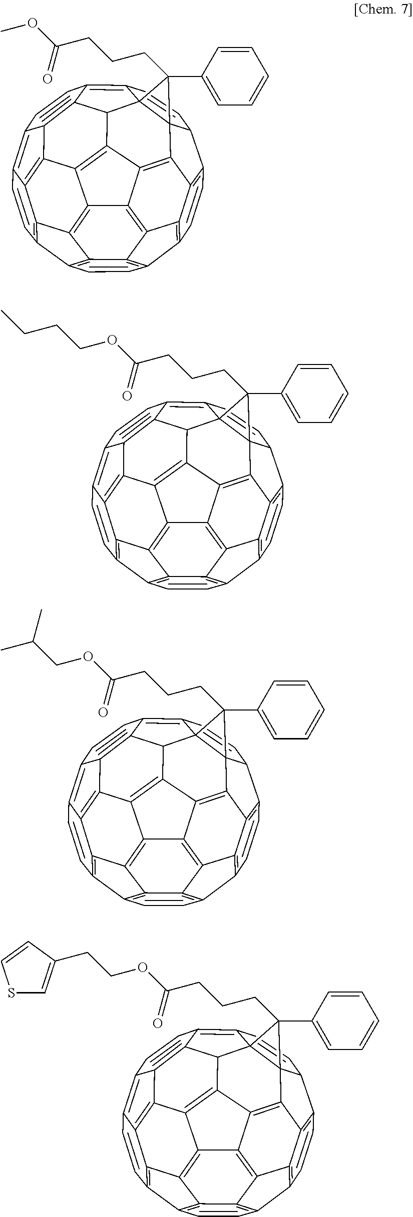

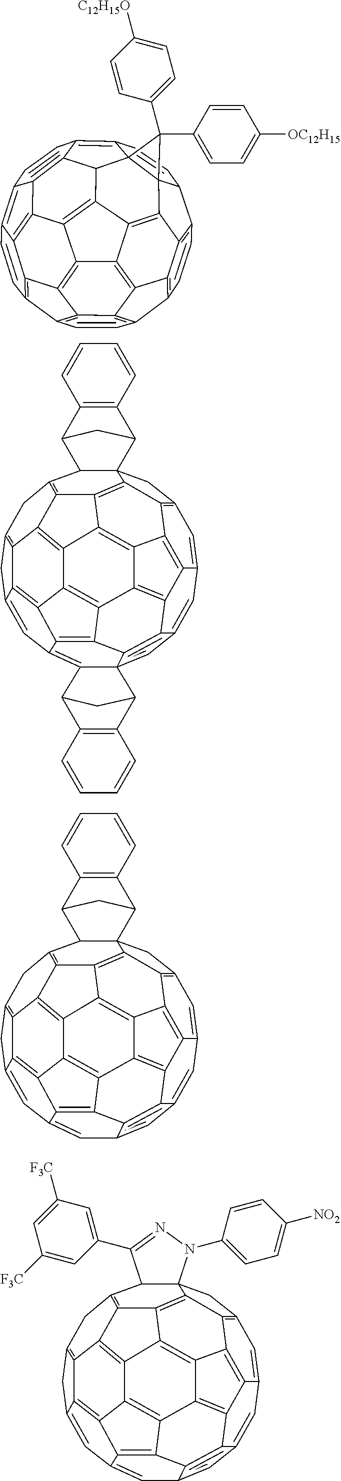

Examples of the electron transport material as the inorganic compound may include zinc oxide, titanium oxide, zirconium oxide, tin oxide, indium oxide, ITO, FTO, gallium-doped zinc oxide (GZO), antimony-doped tin oxide (ATO), and aluminum-doped zinc oxide (AZO); among these oxides, preferred are zinc oxide, gallium-doped zinc oxide, and aluminum-doped zinc oxide. When the electron transport layer containing the electron transport material as the inorganic compound apart from the fullerene derivative represented by Formula (1) is formed, the electron transport layer is preferably formed by causing the inorganic compound to be pulverized and contained in an coating liquid in addition to the fullerene derivative represented by Formula (1) and applying this coating liquid. The electron transport material containing the pulverized inorganic compound is preferably the electron transport material containing nano particles of zinc oxide, gallium-doped zinc oxide, or aluminum-doped zinc oxide. The electron transport material as the inorganic compound is preferably formed of the nanoparticles of zinc oxide, gallium-doped zinc oxide, or aluminum-doped zinc oxide alone. The sphere-equivalent average particle diameter of zinc oxide, gallium-doped zinc oxide, or aluminum-doped zinc oxide is preferably 1 nm to 1,000 nm and more preferably 10 nm to 100 nm. The average particle diameter can be measured by laser light scattering or X-ray diffractometry.

(Method for Forming Electron Transport Layer)

There is no particular limit to a method for forming the electron transport layer. Examples of the method for forming the electron transport layer may include vacuum evaporation and coating method. The electron transport layer is preferably formed by coating method.

An coating liquid used when the electron transport layer is formed by coating method can contain another electron transport material as needed in addition to the fullerene derivative represented by Formula (1). The electron transport layer is preferably formed by applying the coating liquid containing the fullerene derivative represented by Formula (1), the other electron transport material added as needed, and a solvent onto the active layer. For the coating liquid, preferred is an coating liquid that does not damage or hardly damages a layer (the active layer or the like) onto which the coating liquid is to be applied; specifically, the coating liquid preferably does not dissolve or hardly dissolves the layer (the active layer or the like) onto which the coating liquid is to be applied.

Examples of the solvent contained in the coating liquid for forming the electron transport layer may include alcohols, ketones, and hydrocarbons. Specific examples of the alcohols may include methanol, ethanol, isopropanol (2-propanol), butanol, ethylene glycol, propylene glycol, butoxyethanol, and methoxybutanol. Specific examples of the ketones may include acetone, methyl ethyl ketone, methyl isobutyl ketone, 2-heptanone, and cyclohexanone. Specific examples of the hydrocarbons may include n-pentane, cyclohexane, n-hexane, benzene, toluene, xylene, tetralin, chlorobenzene, and ortho-dichlorobenzene. The coating liquid for forming the electron transport layer may contain two or more solvents or contain two or more of the solvents exemplified above. The amount of the solvent used is preferably 1 time or more and 10,000 times or less and more preferably 10 times or more and 1,000 times or less the fullerene derivative represented by Formula (1) and the other electron transport material added as needed in terms of weight.

The coating solution containing the solvent, the fullerene derivative represented by Formula (1), and the other electron transport material as needed is preferably used after being filtered and is preferably filtered using a filter formed of a fluorine-containing resin (Teflon (registered trademark), for example) with a pore diameter of 0.5 μm or the like.

In forming the electron transport layer by applying the coating liquid, the solvent is preferably removed. Examples of a method for removing the solvent may include a method similar to the method for removing the solvent described in the method for forming the active layer.

It is only required for the photoelectric conversion device according to the present invention to provide the active layer between the cathode and the anode and to provide the electron transport layer between the cathode and the active layer; the cathode, the electron transport layer, the active layer, and the anode may be provided in this order on the substrate, or the anode, the active layer, the electron transport layer, and the cathode may be provided in this order on the substrate. The photoelectric conversion device according to the present invention is preferably a photoelectric conversion device that further comprises the supporting substrate and provides the supporting substrate, the anode, the active layer, the electron transport layer, and the cathode in this order.

(Any Other Layers)

The photoelectric conversion device according to the present invention may comprise any other layers exhibiting various functions apart from the active layer and the electron transport layer. Examples of any other layers may include a hole injection layer and a hole transport layer.

(Hole Injection Layer)

The photoelectric conversion device according to the present invention may further comprise the hole injection layer that is provided between the anode and the active layer and contains one or more selected from the group consisting of an aromatic amine compound and a polymer compound containing a repeating unit having an aromatic amine residue.

The hole injection layer is provided between the anode and the active layer and has a function of promoting the injection of holes into the anode. The hole injection layer is preferably provided adjacent to the anode. The material of the hole injection layer is preferably a material that can make the formed hole injection layer water-insoluble.

The material that can make the formed hole injection layer water-insoluble may be either an organic material or an inorganic material. For the material that can make the formed hole injection layer water-insoluble, two or more materials may be used in combination.

Specific examples of the material that can make the formed hole injection layer water-insoluble may include polyaniline and derivatives thereof, polythiophene and derivatives thereof, polypyrrole and derivatives thereof, polymer compounds such as the polymer compound containing a repeating unit having an aromatic amine residue, low molecular weight compounds such as aniline, thiophene, pyrrole, and aromatic amine compounds, and inorganic compounds such as CuSCN and CuI. The material that can make the formed hole injection layer water-insoluble is preferably one or more selected from the group consisting of polythiophene and derivatives thereof, aromatic amine compounds, the polymer compound containing a repeating unit having an aromatic amine residue, and CuSCN and CuI. In view of making initial photoelectric conversion efficiency favorable, the material that can make the formed hole injection layer water-insoluble is preferably one or more selected from the group consisting of aromatic amine compounds and the polymer compound containing a repeating unit having an aromatic amine residue. Among the polymer compounds as the material that can make the formed hole injection layer water-insoluble, more preferred is the polymer compound containing a repeating unit having an aromatic amine residue in view of extending the life of the photoelectric conversion device.

Specific examples of the aromatic amine compound may include compounds represented by the formulae below.

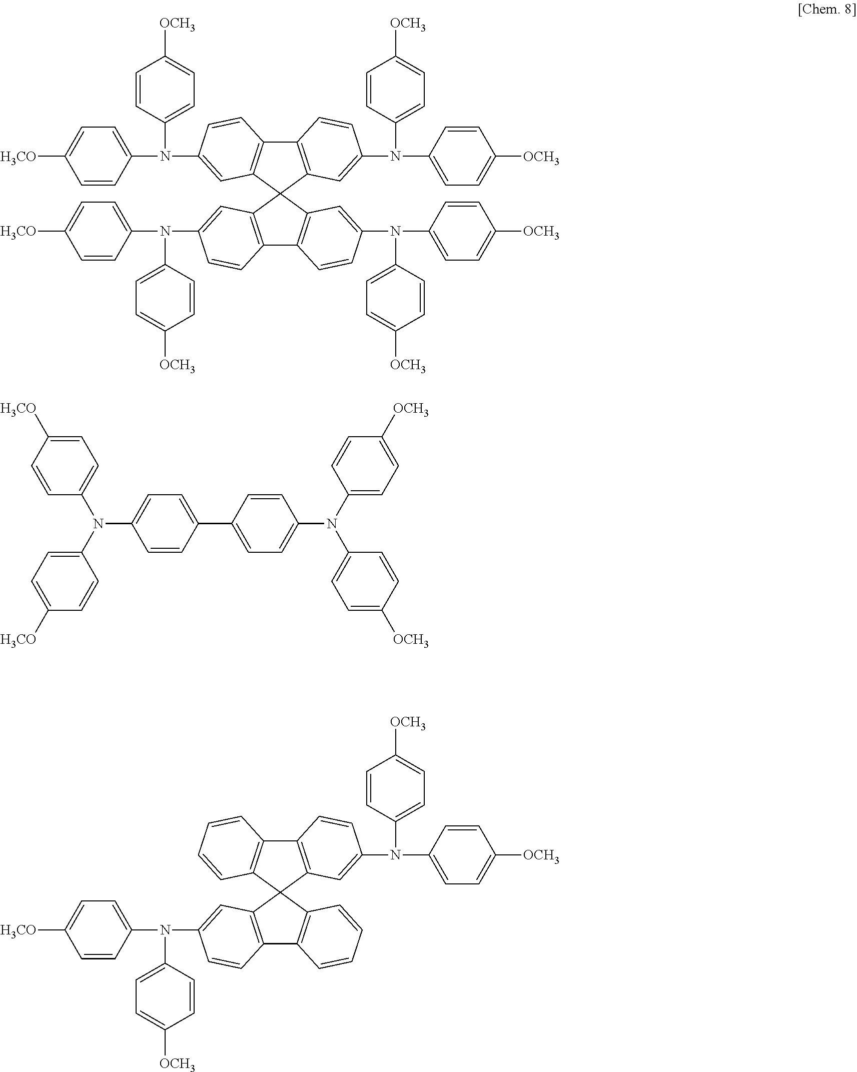

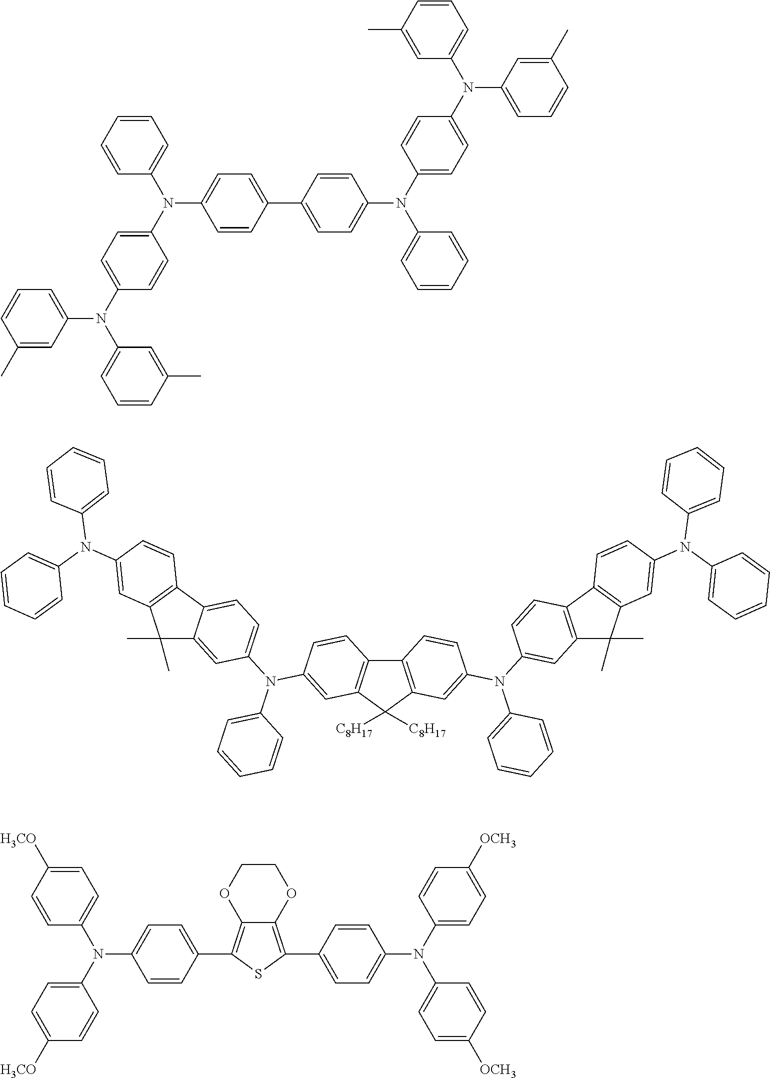

The aromatic amine compound preferably contains a phenyl group having at least three substituents.

Examples of the substituents that the phenyl group contained in the aromatic amine compound can have may include an alkyl group, an alkoxy group, an amino group, and a silyl group.

Specific examples of the aromatic amine compound containing a phenyl group having at least three substituents may include compounds represented by the formulae below.

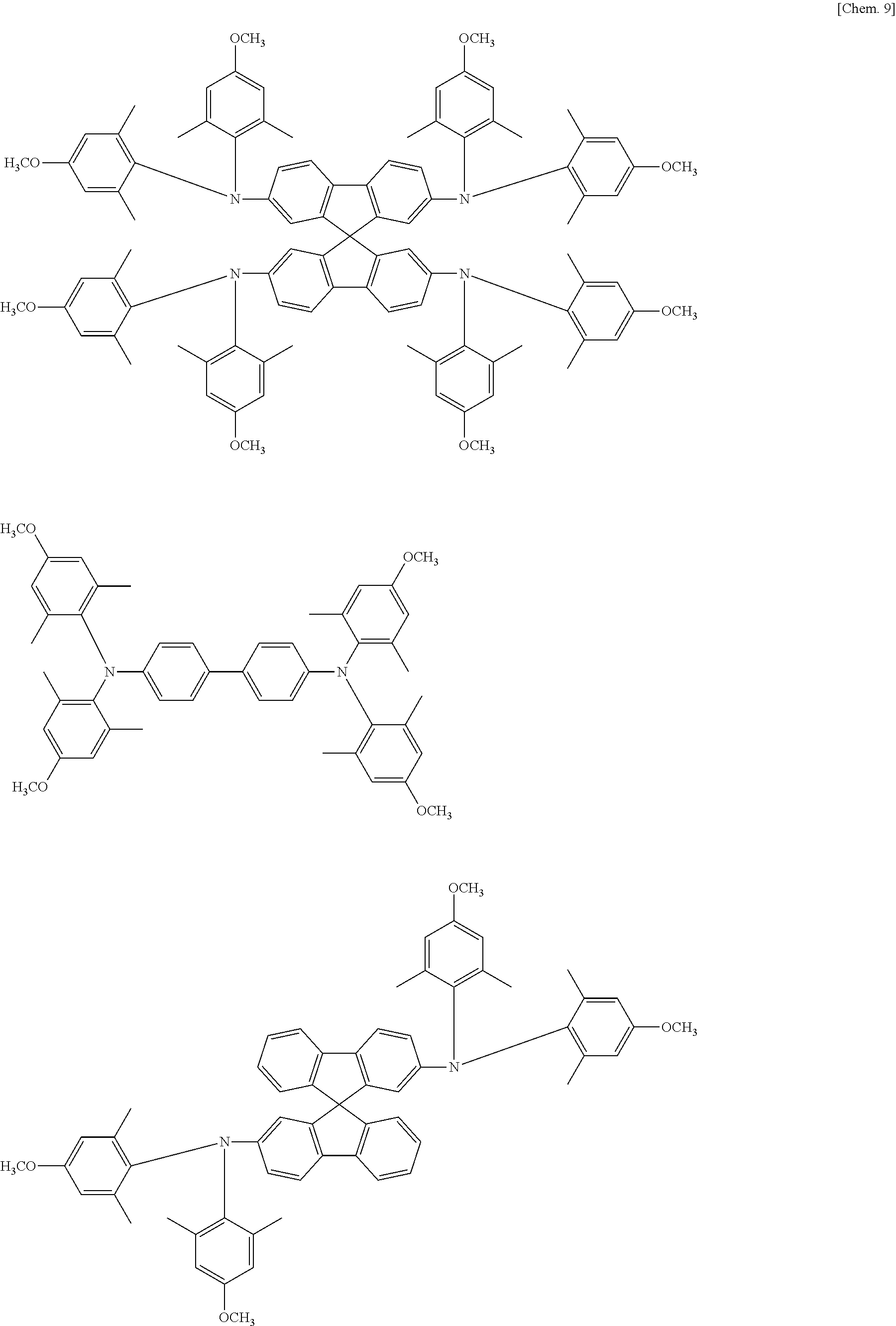 [SMILES: COc1cc(C)c(N(c2ccc3c(c2)C2(c4cc(N(c5c(C)cc(OC)cc5C)c5c(C)cc(OC)cc5C)ccc4-3)c3cc(N(c4c(C)cc(OC)cc4C)c4c(C)cc(OC)cc4C)ccc3-c3ccc(N(c4c(C)cc(OC)cc4C)c4c(C)cc(OC)cc4C)cc32)c2c(C)cc(OC)cc2C)c(C)c1 ; COc1cc(C)c(N(c2ccc(-c3ccc(N(c4c(C)cc(OC)cc4C)c4c(C)cc(OC)cc4C)cc3)cc2)c2c(C)cc(OC)cc2C)c(C)c1 ; COc1cc(C)c(N(c2ccc3c(c2)C2(c4ccccc4-3)c3ccccc3-c3ccc(N(c4c(C)cc(OC)cc4C)c4c(C)cc(OC)cc4C)cc32)c2c(C)cc(OC)cc2C)c(C)c1]

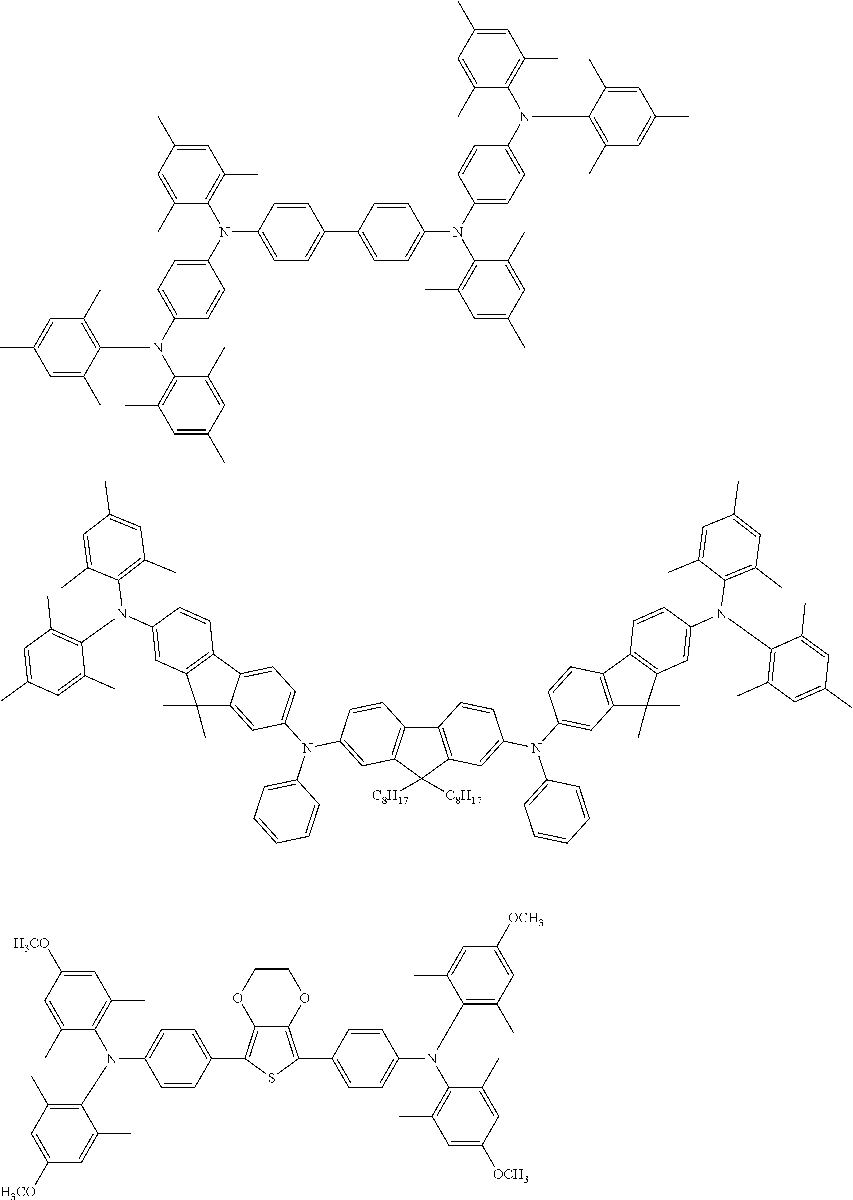

In the polymer compound containing a repeating unit having an aromatic amine residue, the repeating unit having an aromatic amine residue is a repeating unit obtained by eliminating two hydrogen atoms from an aromatic amine compound. Examples of the repeating unit having an aromatic amine residue may include a repeating unit represented by Formula (4′) below. The repeating unit represented by Formula (4′) below is preferably a repeating unit represented by Formula (4) below. The polymer compound containing a repeating unit having an aromatic amine residue preferably contains a phenyl group having at least three substituents.

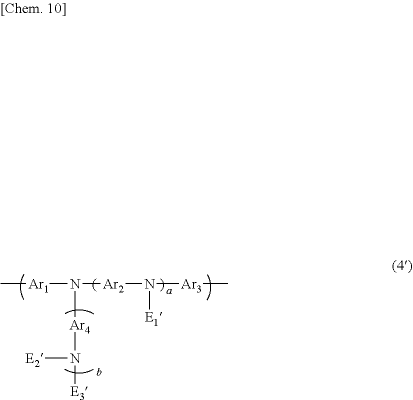

In Formula (4′), Ar₁, Ar₂, Ar₃, and Ar₄ each independently represent an arylene group (A1) or a divalent heterocyclic group (B1). E₁′, E₂′, and E₃′ each independently represent an aryl group (A2′) or a monovalent heterocyclic group (B2′). a and b each independently represent 0 or 1 in which 0≦a+b≦1.

Arylene group (A1): the arylene group (A1) is an atomic group obtained by eliminating two hydrogen atoms from an aromatic hydrocarbon and also includes a divalent group having a benzene ring or a condensed ring and a divalent group in which two or more independent benzene rings or condensed rings are bonded to each other directly or via a vinylene group or the like. The arylene group (A1) optionally has a substituent. Examples of the substituent that the arylene group (A1) can have may include an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a halogen atom, an acyl group, an acyloxy group, an imine residue, an amido group, an acid imide group, a monovalent heterocyclic group, a carboxy group, a substituted carboxy group, and a cyano group; preferred are an alkyl group, an alkoxy group, an alkylthio group, an aryl group, an aryloxy group, an arylthio group, a substituted amino group, a substituted silyl group, a substituted silyloxy group, and a monovalent heterocyclic group. The number of carbon atoms in the arylene group having no substituent is generally about 6 to 60 and preferably 6 to 20.

Divalent heterocyclic group (B1): the divalent heterocyclic group (B1) is a residual atomic group obtained by eliminating two hydrogen atoms from a heterocyclic compound; the divalent heterocyclic group (B1) optionally has a substituent.

The heterocyclic compound refers to, among organic compounds having a cyclic structure, a compound in which the element contained in its ring is not limited to a carbon atom but contains a heteroatom such as an oxygen atom, a sulfur atom, a nitrogen atom, a phosphorus atom, a boron atom, or an arsenic atom within the ring. Example of the substituent that the divalent heterocyclic group (B1) can have may include an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a halogen atom, an acyl group, an acyloxy group, an imino group, an amido group, an imide group, a monovalent heterocyclic group, a carboxy group, a substituted carboxy group, and a cyano group; preferred are an alkyl group, an alkoxy group, an alkylthio group, an aryl group, an aryloxy group, an arylthio group, a substituted amino group, a substituted silyl group, a substituted silyloxy group, and a monovalent heterocyclic group. The number of carbon atoms in the divalent heterocyclic group having no substituent is generally about 3 to 60.

Aryl group (A2′): the aryl group (A2′) optionally has a substituent. Examples of the substituent that the aryl group (A2′) can have may include an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group, and a halogen atom. The number of carbon atoms in the aryl group having no substituent is generally about 6 to 30 and preferably 6 to 20.

Monovalent heterocyclic group (B2′): the monovalent heterocyclic group (B2′) optionally has a substituent. Examples of the substituent that the monovalent heterocyclic group (B2′) can have may include an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group, and a halogen atom. The number of carbon atoms in the monovalent heterocyclic group having no substituent is generally about 1 to 30.

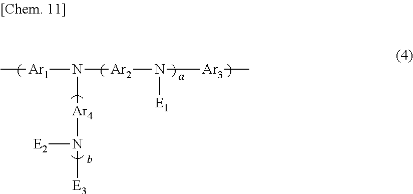

In Formula (4), Ar₁, Ar₂, Ar₃, and Ar₄ represent the same meanings as the above. E₁, E₂, and E₃ each independently represent an aryl group (A2) or a monovalent heterocyclic group (B2) defined as below. a and b represent the same meanings as the above.

Arylene group (A1): the arylene group (A1) is an atomic group obtained by eliminating two hydrogen atoms from an aromatic hydrocarbon and may also include a divalent group having a benzene ring or a condensed ring and a divalent group in which two or more independent benzene rings or condensed rings are bonded to each other directly or via a vinylene group or the like. The arylene group (A1) optionally has a substituent. Examples of the substituent that the arylene group (A1) can have may include an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a halogen atom, an acyl group, an acyloxy group, an imine residue, an amido group, an acid imide group, a monovalent heterocyclic group, a carboxy group, a substituted carboxy group, and a cyano group; preferred are an alkyl group, an alkoxy group, an alkylthio group, an aryl group, an aryloxy group, an arylthio group, a substituted amino group, a substituted silyl group, a substituted silyloxy group, and a monovalent heterocyclic group. The number of carbon atoms in the arylene group having no substituent is generally about 6 to 60 and preferably 6 to 20.

Divalent heterocyclic group (B1): the divalent heterocyclic group (B1) is a residual atomic group obtained by eliminating two hydrogen atoms from a heterocyclic compound; the divalent heterocyclic group (B1) optionally has a substituent.

The heterocyclic compound refers to, among organic compounds having a cyclic structure, a compound in which the element contained in its ring is not limited to a carbon atom and that contains a heteroatom such as an oxygen atom, a sulfur atom, a nitrogen atom, a phosphorus atom, a boron atom, or an arsenic atom within the ring. Example of the substituent that the divalent heterocyclic group (B1) can have may include an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a halogen atom, an acyl group, an acyloxy group, an imino group, an amido group, an imide group, a monovalent heterocyclic group, a carboxy group, a substituted carboxy group, and a cyano group; preferred are an alkyl group, an alkoxy group, an alkylthio group, an aryl group, an aryloxy group, an arylthio group, a substituted amino group, a substituted silyl group, a substituted silyloxy group, and a monovalent heterocyclic group. The number of carbon atoms in the divalent heterocyclic group having no substituent is generally about 3 to 60.

Aryl group (A2): the aryl group (A2) is an aryl group having three or more substituents selected from the group consisting of an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group, and a halogen atom. The number of carbon atoms in the aryl group (A2) is generally about 6 to 40 and preferably 6 to 30.

Monovalent heterocyclic group (B2): the monovalent heterocyclic group (B2) is a monovalent heterocyclic group that has one or more substituents selected from the group consisting of an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group, and a halogen atom and in which the sum of the number of the substituents and the number of hetero atoms of its heterocycle is three or more. The number of carbon atoms in the monovalent heterocyclic group (B2) is generally about 1 to 40.

The aryl group (A2) is preferably a phenyl group having three or more substituents, a naphthyl group having three or more substituents, or an anthracenyl group having three or more substituents; the aryl group (A2) is more preferably a group represented by Formula (5) below.

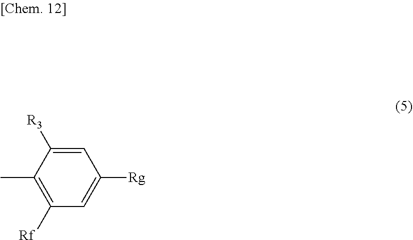

In Formula (5), Re, Rf, and Rg each independently represent an alkyl group, an alkoxy group, an alkylthio group, an aryl group, an aryloxy group, an arylthio group, an arylalkyl group, an arylalkoxy group, an arylalkylthio group, an arylalkenyl group, an arylalkynyl group, an amino group, a substituted amino group, a silyl group, a substituted silyl group, a silyloxy group, a substituted silyloxy group, a monovalent heterocyclic group, or a halogen atom.

The polymer compound containing a repeating unit containing an aromatic amine residue may further have a repeating unit represented by Formula (6), Formula (7), Formula (8), or Formula (9) below.

—Ar₁₂— (6)

—Ar₁₂—X₁—(Ar₁₃—X₂)_{c}—Ar₁₄— (7)

—Ar₁₂—X₂— (8)

—X₂— (9)

In Formula (6) to Formula (9), Ar₁₂, Ar₁₃, and Ar₁₄ each independently represent an arylene group, a divalent heterocyclic group, or a divalent group having a metal complex structure. X₁ represents a group represented by —CR₂═CR₃—, a group represented by —C≡C—, or a group represented by —(SiR₅R₆)_{d}—.

X₂ represents a group represented by —CR₂═CR₃—, a group represented by —C≡C—, a group represented by —N(R₄)—, or a group represented by —(SiR₅R₆)_{d}—. R₂ and R₃ each independently represent a hydrogen atom, an alkyl group, an aryl group, a monovalent heterocyclic group, a carboxy group, a substituted carboxy group, or a cyano group. R₄, R₅, and R₆ each independently represent a hydrogen atom, an alkyl group, an aryl group, a monovalent heterocyclic group, or an arylalkyl group. c represents an integer of 0 to 2. d represents an integer of 1 to 12. When each of Ar₁₃, R₂, R₃, R₅, and R₆ is plurally present, they each may be the same or different from each other.

Examples of the repeating unit represented by Formula (4′) (including examples of the repeating unit represented by Formula (4)) may include a repeating unit in which Ar₁, Ar₂, Ar₃, and Ar₄ are each independently a phenylene group having no substituent, a=1, and b=0; specific examples thereof may include repeating units represented by the formulae below.

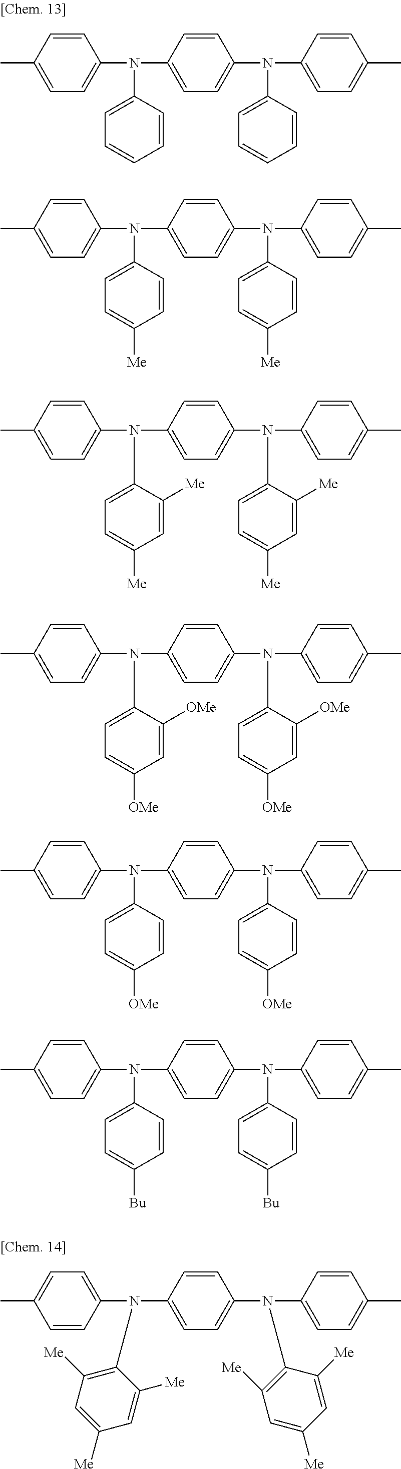

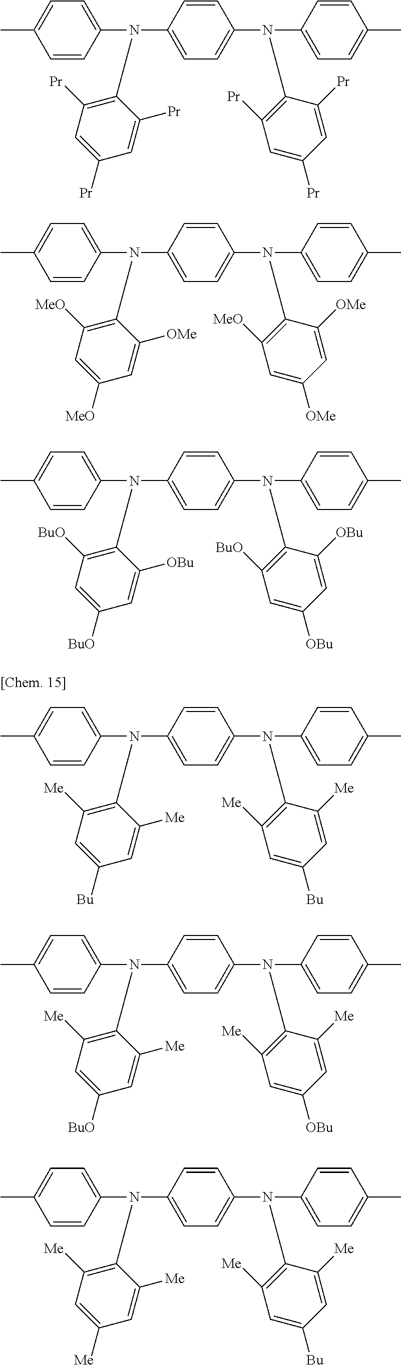

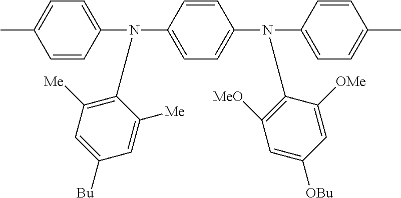

Examples of the repeating unit represented by Formula (4′) (including examples of the repeating unit represented by Formula (4)) may include a repeating unit in which Ar₁, Ar₂, Ar₃, and Ar₄ are each independently a phenylene group having no substituent, a=0, and b=1; specific examples thereof may include repeating units represented by the formulae below.

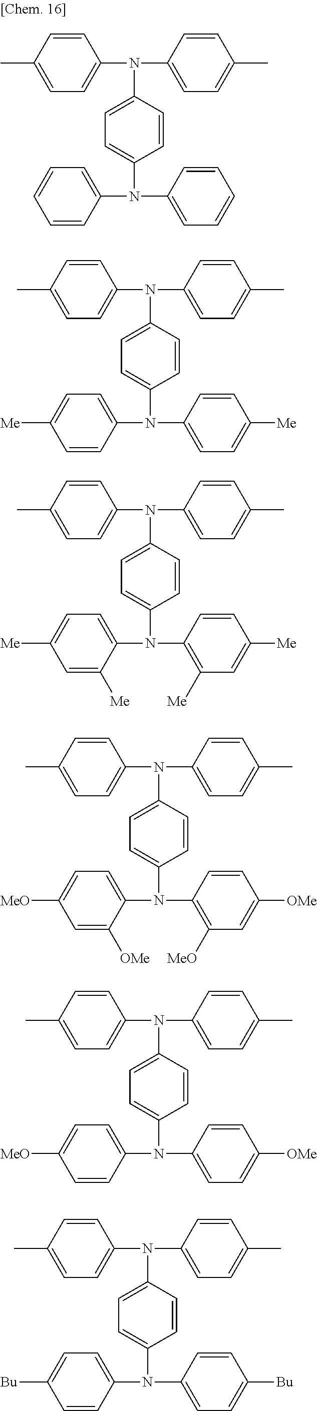

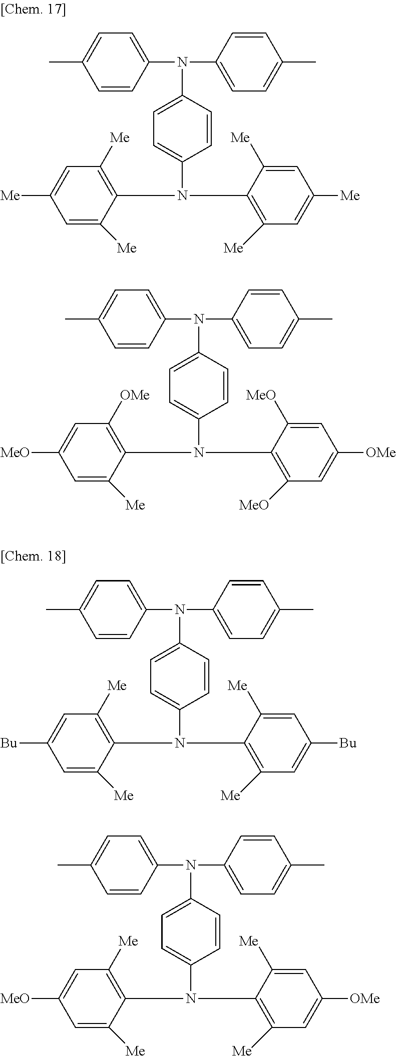

In the above formulae, Me represents a methyl group, Pr represents a propyl group, Bu represents a butyl group, MeO represents a methoxy group, and BuO represents a butyloxy group.

The thickness of the hole injection layer is preferably 25 nm or less, more preferably 20 nm or less, further preferably 15 nm or less, and particularly preferably 10 nm or less.

(Method for Forming Hole Injection Layer)

A method for forming the hole injection layer is not limited to a particular method. The hole injection layer can be formed by applying, for example, an coating liquid containing the component of the hole injection layer described above and a solvent onto a layer on which the hole injection layer is to be formed.

In view of simplifying the formation process, the hole injection layer is preferably formed by coating method. An coating liquid used in coating method contains a solvent and the component of the hole injection layer already described.

Examples of the solvent may include water, alcohols, ketones, and hydrocarbons. Specific examples of the alcohols may include methanol, ethanol, isopropanol, butanol, ethylene glycol, propylene glycol, butoxyethanol, and methoxybutanol. Specific examples of the ketones may include acetone, methyl ethyl ketone, methyl isobutyl ketone, 2-heptanone, and cyclohexanone. Specific examples of the hydrocarbons may include n-pentane, cyclohexane, n-hexane, benzene, toluene, xylene, tetralin, chlorobenzene, and ortho-dichlorobenzene. The solvent may contain two or more components or contain two or more of the solvents exemplified above. The amount of the solvent in the coating liquid is preferably 1 time by weight or more and 10,000 times by weight or less and more preferably 10 times by weight or more and 1,000 times by weight or less of the component of the hole injection layer.

Specific examples and preferred examples of a method for applying the coating liquid containing the component of the hole injection layer and the solvent may include the method for forming the active layer already described.

In forming the hole injection layer by applying the coating liquid, the solvent is preferably removed. Examples of a method for removing the solvent include the method already described as the method for removing the solvent in the formation process of the active layer.

(Hole Transport Layer)

The hole transport layer is provided between the hole injection layer and the active layer and has a function of transporting holes and blocking electrons. Providing the hole transport layer can achieve the photoelectric conversion device with higher efficiency. Examples of the hole transport layer may include low molecular weight compounds containing an amine residue and polymer compounds containing a repeating unit having an amine residue. When the hole injection layer contains a low molecular weight compound having an aromatic amine residue and the polymer compound containing a repeating unit having an aromatic amine residue, such a hole transport layer is not particularly necessarily provided.

The polymer compounds that can be contained in the hole transport layer contain a repeating unit having an amine residue. Examples of the repeating unit that the polymer compounds can contain may include repeating units represented by the formulae below.

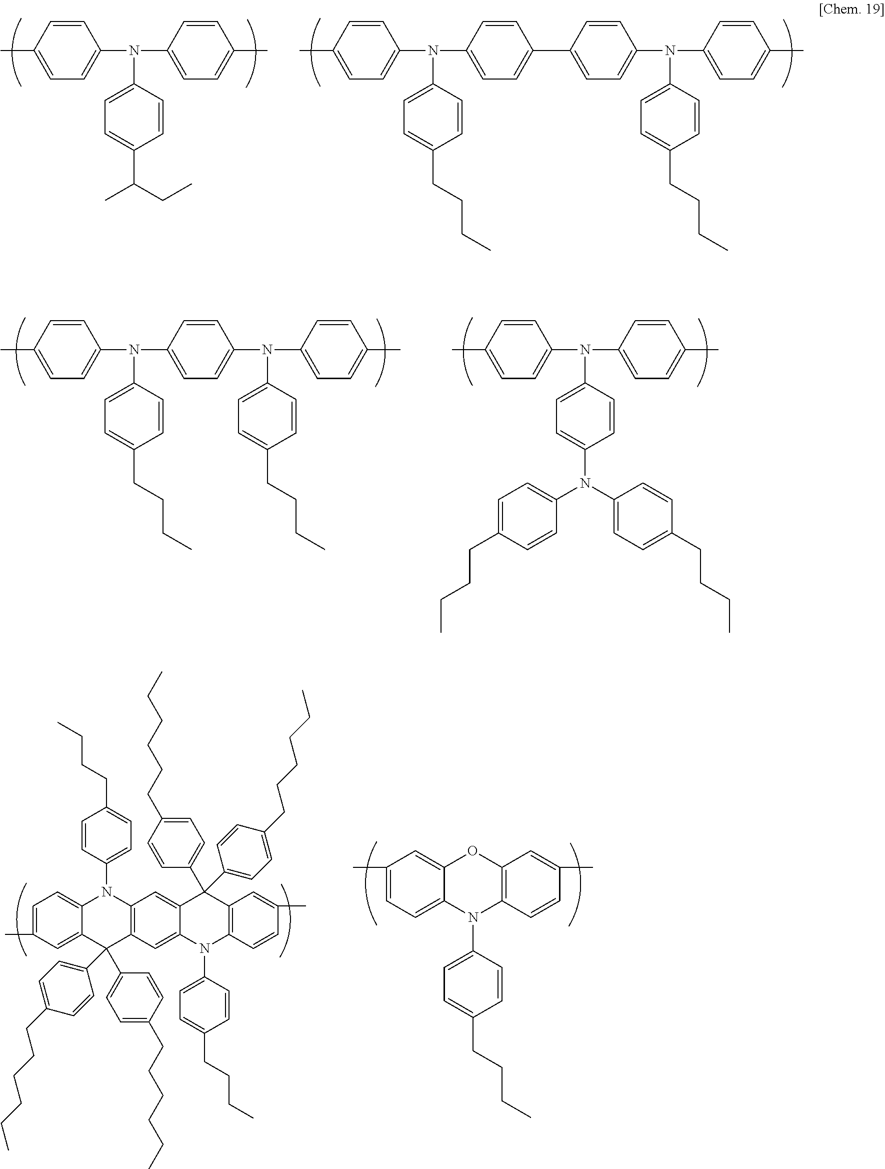

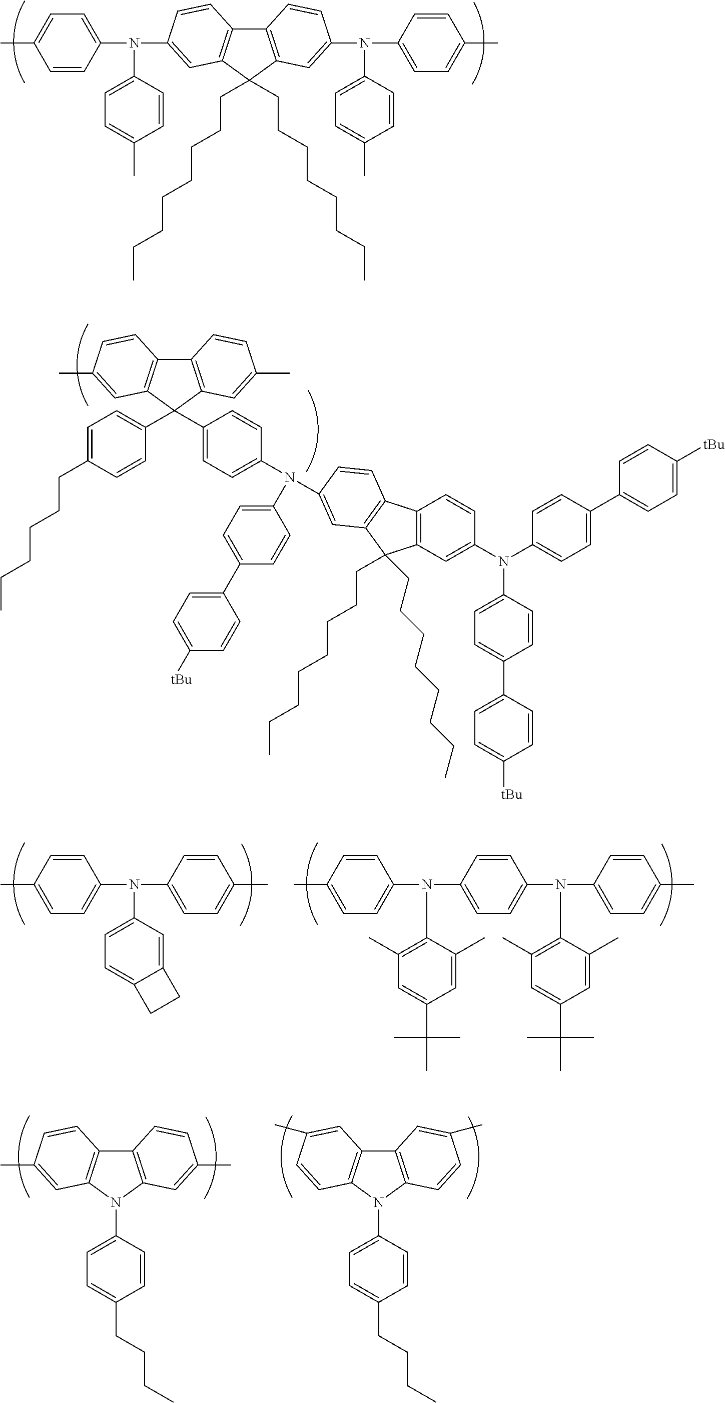

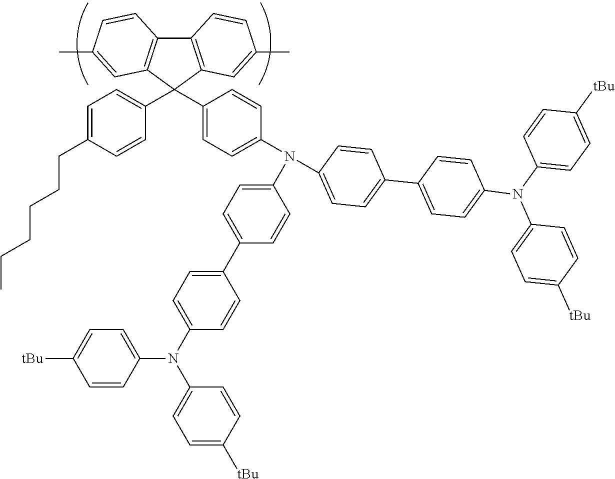

(Method for Forming Hole Transport Layer)

The hole transport layer can be formed similarly to the hole injection layer and the active layer already described.

Specific examples and preferred examples of a method of formation that applies an coating liquid containing the component of the hole transport layer and a solvent may include the method already described in the method for forming the active layer.

In forming the hole transport layer after the coating of the coating liquid, the solvent is preferably removed. Examples of a method for removing the solvent may include the method already described as the method for removing the solvent in the formation process of the active layer.

By irradiating the transparent or semi-transparent electrode with light such as sunlight, photovoltage is generated between the electrodes, and the photoelectric conversion device according to the present invention can be operated as a solar cell. The solar cell comprising the photoelectric conversion device according to the present invention is preferably an organic-inorganic perovskite solar cell containing a perovskite compound with an organic-inorganic hybrid structure in the active layer. By integrating a plurality of such solar cells, they can also be used as an organic thin film solar cell module.

By irradiating the transparent or semi-transparent electrode with light with voltage applied between the electrodes, an optical current can pass therebetween, and the photoelectric conversion device according to the present invention can be operated as an optical sensor. By integrating a plurality of such optical sensors, they can also be used as an image sensor.

### EXAMPLES

The following shows examples in order to describe the present invention in more detail; the present invention is not limited to these examples.

(Preparation of Composition 1)

Lead iodide in an amount of 460 mg was dissolved in 1 mL of N,N-dimethylformamide and was completely dissolved therein by stirring the solution at 70° C. to prepare Composition 1.

(Preparation of Composition 2)

Methylammonium iodide in an amount of 45 mg was completely dissolved in 1 mL of 2-propanol to prepare Composition 2.

(Preparation of Composition 3)

[6,6]-Phenyl C61-butyric acid methyl ester (C60PCBM) (E100 manufactured by Frontier Carbon Corporation) in an amount of 1 part by weight as a fullerene derivative and 100 parts by weight of chlorobenzene as a solvent were mixed and completely dissolved with each other to prepare Composition 3.

(Preparation of Composition 4)

[6,6]-Phenyl C71-butyric acid methyl ester (C70PCBM) (ADS71BFA manufactured by American Dye Source, Inc.) in an amount of 1 part by weight as a fullerene derivative and 100 parts by weight of chlorobenzene as a solvent were mixed and completely dissolved with each other to prepare Composition 4.

(Preparation of Composition 5)

A compound represented by the formula below in an amount of 1 part by weight as the fullerene derivative represented by Formula (1) and 100 parts by weight of chlorobenzene as a solvent were mixed and completely dissolved with each other to prepare Composition 5.

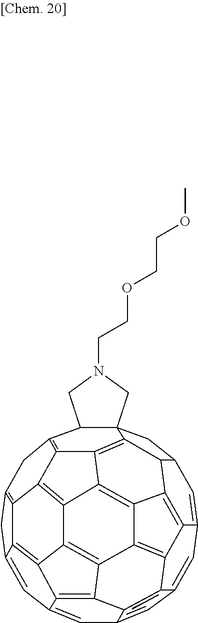 [SMILES: COCCOCCN1CC2C3=c4c5c6c7c8c9c%10c7c7c%11c%12c(cc%13c%14c(c4c6c7c%12%14)=C(C3)C%13)=CC3=CC(=CC9=CC4CC2(C1)C=5C84)C%10C3%11]

(Preparation of Composition 6)

A compound represented by the formula below in an amount of 1 part by weight as the fullerene derivative represented by Formula (1) and 100 parts by weight of chlorobenzene as a solvent were mixed and completely dissolved with each other to prepare Composition 6.

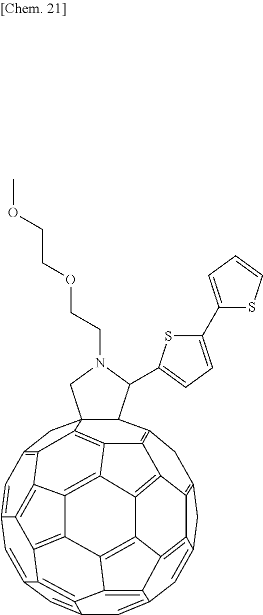 [SMILES: COCCOCCN1CC23Cc4cc5cc6cc7cc8cc9c%10c%11c%12c(c%13c2c4c2c5c4c6c7c5c8c%10c6c%12c%13c2c4c56)=C(CC=%11C9)C3C1c1ccc(-c2cccs2)s1]

(Preparation of Composition 7)

A compound represented by the formula below (the ring attached with the figure “70” means a C₇₀ fullerene skeleton) in an amount of 1 part by weight as the fullerene derivative represented by Formula (1) and 100 parts by weight of chlorobenzene as a solvent were mixed and completely dissolved with each other to prepare Composition 7.

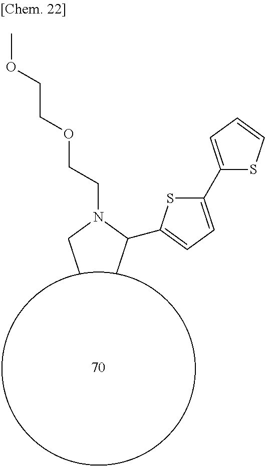 [SMILES: CCN(CCOCCOC)C(C)c1ccc(-c2cccs2)s1]

(Preparation of Composition 8)

A compound represented by the formula below in an amount of 1 part by weight as the fullerene derivative represented by Formula (1) and 100 parts by weight of chlorobenzene as a solvent were mixed and completely dissolved with each other to prepare Composition 8.

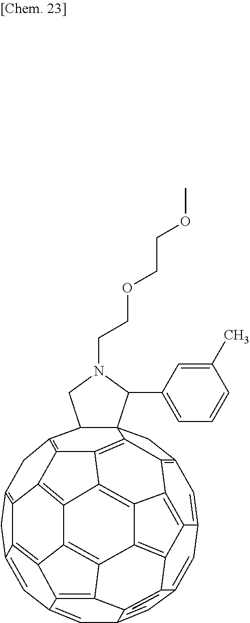 [SMILES: COCCOCCN1CC2C3=c4c5c6c7c(cc8c9c%10c%11c%12c%13c%14c(cc%15c%16c(c4c(c5c%11c79)c%12c%14%16)=C(C3)C%15)=CC3=CC(=C8)C%10C3%13)CC62C1c1cccc(C)c1]

(Preparation of Composition 9)

A compound represented by the formula below in an amount of 1 part by weight as the fullerene derivative represented by Formula (1) and 100 parts by weight of chlorobenzene as a solvent were mixed and completely dissolved with each other to prepare Composition 9.

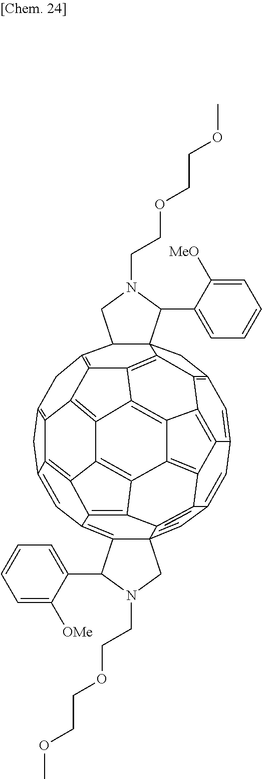

(Preparation of Composition 10)

A compound represented by the formula below in an amount of 0.5 part by weight as the fullerene derivative represented by Formula (1), 1.5 parts by weight of [6,6]-phenyl C61-butyric acid methyl ester (C60PCBM) (E100 manufactured by Frontier Carbon Corporation), and 100 parts by weight of chlorobenzene as a solvent were mixed and completely dissolved with each other to prepare Composition 10.

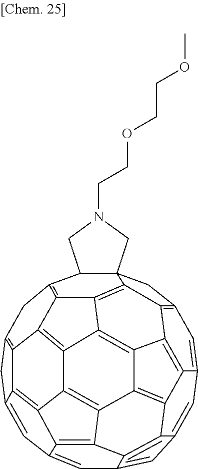 [SMILES: COCCOCCN1CC2C3=c4c5c6c7c(cc8cc9cc%10cc%11cc%12c%13c(c4c4c5c5c7c8c7c9c%10c8c%11c%13c4c8c75)=C(C3)C%12)CC62C1]

### Example 1

### Production and Evaluation of Photoelectric Conversion Device

A glass substrate formed with an ITO thin film functioning as an anode was prepared. The ITO thin film was formed by sputtering, and its thickness was 150 nm. The glass substrate having the ITO thin film was subjected to ozone UV treatment to perform surface treatment on the ITO thin film. Next, Plexcore PV2000 Hole Transport Ink (sulfonated polythiophene(thiophene-3-[2-(2-methoxyethoxy)ethoxy]-2,5-diyl) (S-P3MEET) 1.8% in 2-butoxyethanol:water (2:3)) included in PV2000 kit, an organic solar cell production kit by Sigma-Aldrich) was applied onto the ITO film by a spin coater and was heated in the atmosphere at 170° C. for 10 minutes to form a hole injection layer with a thickness of 50 nm. The substrate formed with the hole injection layer was heated at 70° C. and was then placed on a chuck of the spin coater. Composition 1 heated at 70° C. was applied onto the hole injection layer formed on the substrate using the spin coater at a number of revolutions of 4,000 RPM and was air-dried under a nitrogen gas atmosphere to obtain a lead iodide layer. After that, Composition 2 was dropped onto the lead iodide layer, was subjected to spin coating at 6,000 RPM, and was dried in the atmosphere at 100° C. for 10 minutes to form an active layer containing a perovskite compound with an organic-inorganic hybrid structure. The thickness of the active layer was about 300 nm.

Next, Composition 5 was applied onto the active layer using the spin coater to form an electron transport layer with a thickness of about 50 nm. Subsequently, calcium was deposited thereonto with a thickness of 4 nm by vacuum evaporation, and silver was then deposited thereonto with a thickness of 60 nm by vacuum evaporation to form a cathode. The degree of vacuum during vacuum evaporation was set to 1×10⁻³ to 9×10⁻³ Pa in all the vacuum evaporation processes. Subsequently, under a nitrogen gas atmosphere, sealing glass was caused to adhere to the cathode side face using a UV curable epoxy resin through UV curing to seal, whereby a photoelectric conversion device was produced. The shape of the thus obtained photoelectric conversion device was a square with 2 mm×2 mm.

The obtained photoelectric conversion device was irradiated with constant light using a solar simulator (manufactured by Bunkoukeiki Co., Ltd., trade name: OTENTO-SUNII: AM1.5G Filter, irradiance: 100 mW/cm²), and generated current and voltage were measured to measure initial photoelectric conversion efficiency (initial efficiency). Subsequently, the photoelectric conversion device was held in a weathering tester with conditions of a light intensity of 1 Sun and a constant temperature of 65° C. for 20 hours. The photoelectric conversion device was then irradiated with constant light using the solar simulator (manufactured by Bunkoukeiki Co., Ltd., trade name: OTENTO-SUNII: AM1.5G Filter, irradiance: 100 mW/cm²), and generated current and voltage were measured to measure photoelectric conversion efficiency (efficiency) after 20 hours. The efficiency after 20 hours/the initial efficiency was calculated as a retention rate, which was listed in Table 1 together with the composition used for the formation of the electron transport layer.

### Examples 2 to 6

### Production and Evaluation of Photoelectric Conversion Devices

Photoelectric conversion devices were produced similarly to Example 1 except that composition 5 used for the formation of the electron transport layer was changed to Compositions 6 to 10, and the initial efficiency and the efficiency after 20 hours were measured. The efficiency after 20 hours/the initial efficiency was calculated as a retention rate, which was listed in Table 1 together with the composition used for the formation of the electron transport layer.

### Comparative Examples 1 and 2

### Production and Evaluation of Photoelectric Conversion Devices

Photoelectric conversion devices were produced similarly to Example 1 except that Composition 5 used for the formation of the electron transport layer was changed to Composition 3 (Comparative Example 1) or Composition 4 (Comparative Example 2), and the initial efficiency and the efficiency after 20 hours were measured. The efficiency after 20 hours/the initial efficiency was calculated as a retention rate, which was listed in Table 1 together with the composition used for the formation of the electron transport layer.

The obtained photoelectric conversion device was irradiated with constant light using the solar simulator (manufactured by Bunkoukeiki Co., Ltd., trade name: OTENTO-SUNII: AM1.5G Filter, irradiance: 100 mW/cm²), and generated current and voltage were measured to measure initial photoelectric conversion efficiency (initial efficiency). Subsequently, the photoelectric conversion device was held in a weathering tester with conditions of a light intensity of 1 Sun and a constant temperature of 65° C. for 20 hours. The photoelectric conversion device was irradiated with constant light using the solar simulator (manufactured by Bunkoukeiki Co., Ltd., trade name: OTENTO-SUNII: AM1.5G Filter, irradiance: 100 mW/cm²), and generated current and voltage were measured to measure photoelectric conversion efficiency after 20 hours. The efficiency after 20 hours/the initial efficiency was calculated as a retention rate, which was listed in Table 1 together with the composition used for the formation of the electron transport layer.

(Preparation of Composition 11)

Lead iodide in an amount of 368 mg was dissolved in 1 mL of N,N-dimethylformamide and was completely dissolved therein by stirring the solution at 70° C. to prepare Composition 11.

(Preparation of Composition 12)

Methylammonium iodide in an amount of 45 mg was completely dissolved in 1 mL of 2-propanol to prepare Composition 12.

(Preparation of Composition 13)

[6,6]-Phenyl C61-butyric acid methyl ester (C60PCBM) (E100 manufactured by Frontier Carbon Corporation) in an amount of 2 parts by weight as a fullerene derivative and 100 parts by weight of chlorobenzene as a solvent were mixed and completely dissolved with each other to prepare Composition 13.

(Preparation of Composition 14)

A compound represented by the formula below in an amount of 2 parts by weight as the fullerene derivative represented by Formula (1) and 100 parts by weight of chlorobenzene as a solvent were mixed and completely dissolved with each other to prepare Composition 14.

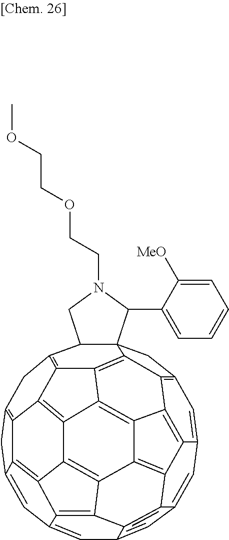 [SMILES: COCCOCCN1CC2C3=c4c5c6c7c(cc8c9c%10c%11c%12c%13c%14c(cc%15c%16c(c4c(c5c%11c79)c%12c%14%16)=C(C3)C%15)=CC3=CC(=C8)C%10C3%13)CC62C1c1ccccc1OC]

(Preparation of Composition 15)

A compound represented by the formula below in an amount of 2 parts by weight as the fullerene derivative represented by Formula (1) and 100 parts by weight of chlorobenzene as a solvent were mixed and completely dissolved with each other to prepare Composition 15.

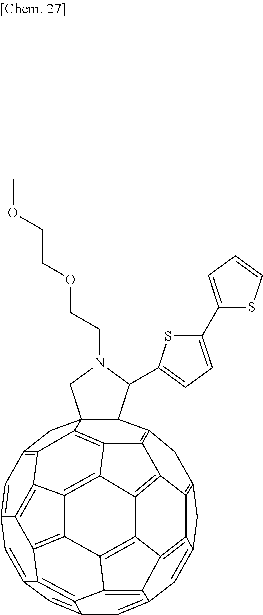 [SMILES: COCCOCCN1CC23Cc4cc5cc6cc7cc8cc9c%10c%11c%12c(c%13c2c4c2c5c4c6c7c5c8c%10c6c%12c%13c2c4c56)=C(CC=%11C9)C3C1c1ccc(-c2cccs2)s1]

(Preparation of Composition 16)

A compound represented by the formula below in an amount of 2 parts by weight as the fullerene derivative represented by Formula (1) and 100 parts by weight of chlorobenzene as a solvent were mixed and completely dissolved with each other to prepare Composition 16.

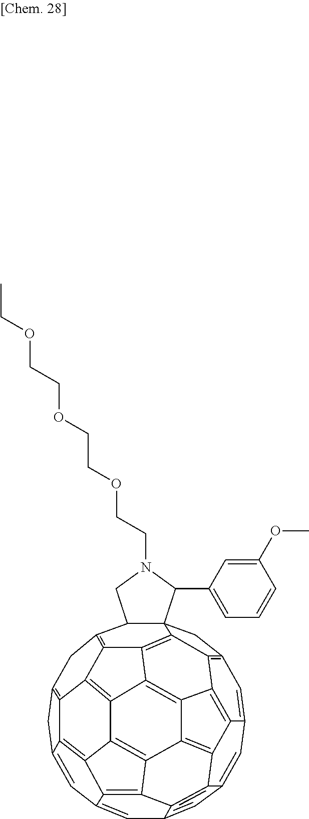 [SMILES: CCOCCOCCOCCN1CC2C3=c4c5c6c7c(cc8c9c%10c%11c%12c%13c%14c(cc%15c%16c(c4c(c5c%11c79)c%12c%14%16)=C(C3)C%15)=CC3=CC(=C8)C%10C3%13)CC62C1c1cccc(OC)c1]

(Preparation of Composition 17)

A polymer compound (manufactured by Sigma-Aldrich, poly[bis(4-phenyl)(2,4,6-trimethylphenyl)amine], average Mn: 7,000 to 10,000) containing a repeating unit represented by the formula below in an amount of 0.5 part by weight and 100 parts by weight of chlorobenzene as a solvent were mixed and completely dissolved with each other to prepare Composition 17.

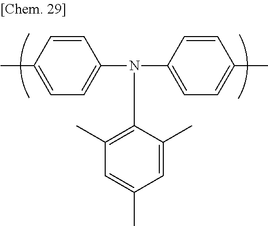

### Example 7

### Production and Evaluation of Photoelectric Conversion Device

A glass substrate formed with an ITO thin film functioning as an anode was prepared. The ITO thin film was formed by sputtering, and its thickness was 150 nm. The glass substrate having the ITO thin film was subjected to ozone UV treatment to perform surface treatment on the ITO thin film. Next, Composition 17 was applied onto the ITO film by a spin coater and was heated in the atmosphere at 120° C. for 10 minutes to form a hole injection layer with a thickness of 10 nm. The substrate formed with the hole injection layer was heated at 70° C. and was then placed on a chuck of the spin coater. Composition 11 heated at 70° C. was applied onto the hole injection layer formed on the substrate using the spin coater at a number of revolutions of 2,000 RPM and was air-dried under a nitrogen gas atmosphere to obtain a lead iodide layer. After that, Composition 12 was dropped onto the lead iodide layer, was subjected to spin coating at 6,000 RPM, and was dried in the atmosphere at 100° C. for 10 minutes to form an active layer containing a perovskite compound with an organic-inorganic hybrid structure. The thickness of the active layer was about 350 nm.

Next, Composition 14 was applied onto the active layer using the spin coater to form an electron transport layer with a thickness of about 50 nm. Subsequently, calcium was deposited thereonto with a thickness of 4 nm by vacuum evaporation, and silver was then deposited thereonto with a thickness of 60 nm by vacuum evaporation to form a cathode. The degree of vacuum during vacuum evaporation was set to 1×10⁻³ to 9×10⁻³ Pa in all the vacuum evaporation processes. Subsequently, under a nitrogen gas atmosphere, sealing glass was caused to adhere to the cathode side face using a UV curable epoxy resin through UV curing to seal, whereby a photoelectric conversion device was produced. The shape of the thus obtained photoelectric conversion device was a square with 2 mm×2 mm.

The obtained photoelectric conversion device was irradiated with constant light using the solar simulator (manufactured by Bunkoukeiki Co., Ltd., trade name: OTENTO-SUNII: AM1.5G Filter, irradiance: 100 mW/cm²), and generated current and voltage were measured to measure initial photoelectric conversion efficiency (initial efficiency). Subsequently, the photoelectric conversion device was held in a weathering tester with conditions of a light intensity of 1 Sun and a constant temperature of 65° C. for 24 hours. The photoelectric conversion device was irradiated with constant light using the solar simulator (manufactured by Bunkoukeiki Co., Ltd., trade name: OTENTO-SUNII: AM1.5G Filter, irradiance: 100 mW/cm²), and generated current and voltage were measured to measure photoelectric conversion efficiency after 24 hours. The efficiency after 24 hours/the initial efficiency was calculated as a retention rate, which was listed in Table 1 together with the composition used for the formation of the electron transport layer.

### Examples 8 and 9

### Production and Evaluation of Photoelectric Conversion Devices

Photoelectric conversion devices were produced similarly to Example 7 except that Composition 14 used for the formation of the electron transport layer was changed to Composition 15 (Example 8) or Composition 16 (Example 9), and the initial efficiency and the photoelectric conversion efficiency after 24 hours were measured. The efficiency after 24 hours/the initial efficiency was calculated as a retention rate, which was listed in Table 2 together with the composition used for the formation of the electron transport layer.

### Comparative Example 3

### Production and Evaluation of Photoelectric Conversion Device

A photoelectric conversion device was produced similarly to Example 7 except that Composition 14 used for the formation of the electron transport layer was changed to Composition 13, and the initial efficiency and the efficiency after 24 hours were measured. The efficiency after 24 hours/the initial efficiency was calculated as a retention rate, which was listed in Table 2 together with the composition used for the formation of the electron transport layer.

TABLE 1

| | Composition | Retention rate |
|---|---|---|
| Example 1 | Composition 5 | 0.94 |
| Example 2 | Composition 6 | 0.99 |
| Example 3 | Composition 7 | 0.91 |
| Example 4 | Composition 8 | 0.86 |
| Example 5 | Composition 9 | 0.995 |
| Example 6 | Composition 10 | 1.01 |
| Comparative | Composition 3 | 0.32 |
| Example 1 | | |
| Comparative | Composition 4 | 0.35 |
| Example 2 | | |

TABLE 2

| | | Initial | |
|---|---|---|---|
| | Composition | efficiency (%) | Retention rate |
| Example 7 | Composition 14 | 12.4 | 1.03 |
| Example 8 | Composition 15 | 11.7 | 0.91 |
| Example 9 | Composition 16 | 11.3 | 1.02 |
| Comparative | Composition 13 | 13.9 | 0.59 |
| Example 3 | | | |

As is clear from Table 1, the photoelectric conversion devices of Examples 1 to 6, which combined the active layer containing the perovskite compound with the organic-inorganic hybrid structure and the electron transport layer containing the fullerene derivative represented by Formula (1), were markedly higher in the retention rate of efficiency than Comparative Examples 1 and 2 and had high durability against light irradiation. In addition, Example 6, in which the electron transport layer contained Composition 10 containing the fullerene derivative other than the fullerene derivative represented by Formula (1) in addition to the fullerene derivative represented by Formula (1), was higher in the retention rate.

As is clear from Table 2, the photoelectric conversion devices of Examples 7 to 9, which combined the active layer containing the perovskite compound with the organic-inorganic hybrid structure and the electron transport layer containing the fullerene derivative represented by Formula (1), were markedly higher in the retention rate than Comparative Example 3 and had high durability against light irradiation. Further, the photoelectric conversion devices of Examples 7 to 9 had high initial efficiency.

### INDUSTRIAL APPLICABILITY

The present invention can improve the durability of a photoelectric conversion device against light irradiation.

1. A photoelectric conversion device comprising:
a cathode;
an anode;
an active layer that is provided between the cathode and the anode and contains a perovskite compound; and
an electron transport layer that is provided between the cathode and the active layer and contains a fullerene derivative represented by Formula (1) below: 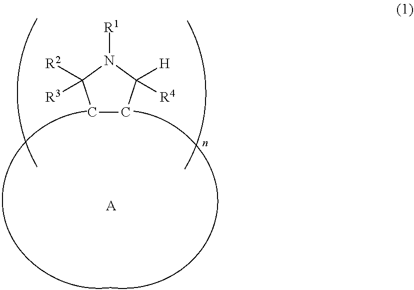
wherein, in Formula (1), Ring A represents a fullerene skeleton; R¹, R², R³, and R⁴ each independently represent a hydrogen atom, a halogen atom, an alkyl group optionally substituted with a halogen atom, an aryl group optionally having a substituent, an arylalkyl group optionally having a substituent, a monovalent heterocyclic group optionally having a substituent, or a group represented by Formula (2) below; and n represents an integer of 1 or more; 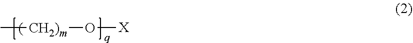
wherein, in Formula (2), m represents an integer of 1 to 6; q represents an integer of 1 to 4; X represents a hydrogen atom, an alkyl group, or an aryl group optionally having a substituent; when m is plurally present, a plurality of ms may be the same or different.

2. The photoelectric conversion device according to claim 1, wherein R¹ is a group represented by Formula (2).

3. The photoelectric conversion device according to claim 1, further comprising a supporting substrate, wherein
the supporting substrate, the anode, the active layer, the electron transport layer, and the cathode are provided in this order.

4. The photoelectric conversion device according to claim 1, further comprising a hole injection layer that is provided between the anode and the active layer and contains one or more selected from the group consisting of an aromatic amine compound and a polymer compound containing a repeating unit having an aromatic amine residue.

5. A solar cell module comprising the photoelectric conversion device according to claim 1.

6. An organic optical sensor comprising the photoelectric conversion device according to claim 1.
